(19) United States
(12) Patent Application Publication
(10) Pub. No.: US 2002/0158303 A1
(43) Pub. Date: Oct. 31, 2002

(54) Semiconductor device and method of fabricating same

(75) Inventors: Takashi Kuroi, Tokyo (JP); Hidekazu Oda, Tokyo (JP); Yukio Nishida, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/173,666

(22) Filed: Jun. 19, 2002

Related U.S. Application Data
(62) Division of application No. 09/244,637, filed on Feb. 4, 1999.

(30) Foreign Application Priority Data
Aug. 20, 1998 (JP) 10-234066

(51) Int. Cl. H01L 21/76

(52) U.S. Cl. 257/510

(57) ABSTRACT

A MOSFET includes a silicon substrate (1) with trenches (2) formed therein. Each of the trenches (2) is completely filled with a silicon oxy-nitride (9) formed on inner wall faces (2W) and a bottom face (2B) thereof. The ratio between compositions of the silicon oxy-nitride (9) is controlled so that the silicon oxy-nitride (9) is approximately equal in thermal expansion coefficient to silicon. An end portion of the silicon oxy-nitride (9) along an opening of each trench (2) is located at a higher level than a main surface (1S) of the silicon substrate (1), and a surface of the silicon oxy-nitride (9) increases in height from the end portion toward the center thereof. The silicon oxy-nitride (9) has no depressions adjacent to the end portion thereof. Sidewall oxide films (41) and a gate electrode (5) are formed on a gate insulation film (4) formed in an active region. Source and drain diffusion layers (6) are formed which have a predetermined depth from the main surface (1S), and LDD layers (42) are formed in contact with the source and drain diffusion layers (6). The MOSFET includes a trench-type isolation having an improved isolation characteristic for reduction in leakage current.

### BACKGROUND OF THE INVENTION

1. Field of the Invention

The present invention relates to a semiconductor device and a method of fabricating the same. More particularly, the invention relates to a semiconductor device having a trench-isolated structure and a method of fabricating the same.

2. Description of the Background Art

Semiconductor integrated circuits are required to eliminate electric interference between individual devices thereof for completely independent control of the devices in operation. To meet this requirement, the semiconductor integrated circuits employ an isolated structure having an isolation region. One of the widely known methods of forming such an isolated structure includes a trench isolation technique, and numerous improvements thereof have been proposed.

The trench isolation technique is such that a trench formed from the surface of a substrate toward the inside thereof is filled with a dielectric to electrically insulate devices from each other. This technique causes few “bird's beaks” which are found in an isolated structure formed by the LOCOS process. The trench isolation technique is preferred in promoting the size reduction of the semiconductor integrated circuits since a substrate surface area required to form the isolated structure by using the trench isolation technique is less than that required by using the LOCOS process. Therefore, the trench isolation technique may be considered as an essential isolation technique for the semiconductor integrated circuits which will be further reduced in size in the future.

With reference to FIGS. 42 through 47, description is given hereinafter on a prior art trench-isolated semiconductor device (MOSFET herein) and a method of fabricating the same.

FIG. 42 is a vertical sectional view of major parts of the prior art trench-isolated MOSFET. FIG. 43 is an enlarged view of an isolation region 20P and its surrounding parts of the MOSFET of FIG. 42. As shown in FIGS. 42 and 43, trenches 2P having a predetermined depth are formed in the isolation region 20P of a semiconductor substrate 1P made of single crystalline silicon (also referred to hereinafter as a “silicon substrate 1P”). An inner wall oxide film 11P is formed on inner wall faces 2PW and a bottom face 2PB of each of the trenches 2P. Part of the entire surface of the inner wall oxide film 11P which is not in contact with the inner wall faces 2PW and the bottom face 2PB is referred to as a “surface 11PS,” and parts of the surface 11PS which extend along the inner wall faces 2PW and the bottom face 2PB of each trench 2 are referred to as “inner wall faces 11PW” and a “bottom face 11PB,” respectively. Each trench 2 is filled with a silicon oxide 3P formed on the inner wall faces 11PW and the bottom face 11PB. A structure for trench isolation which comprises the inner wall oxide film 11P and the silicon oxide 3P is referred to as a “trench-type isolation 59P” hereinafter.

The isolation region 20P shall not only mean a two-dimensional region extending in the plane of a main surface 1PS of the semiconductor substrate 1P but also include a three-dimensional region extending also in a direction perpendicular to the main surface 1PS of the semiconductor substrate 1P. Thus, a region other than the isolation region 20P means an active region 30P, and the semiconductor substrate 1P is divided into two regions: the isolation region 20P and the active region 30P.

A gate insulation film 4P is formed in a predetermined position on the main surface 1PS in the active region 30P, and a gate electrode 5P is formed in a predetermined region on the surface of the gate insulation film 4P. Sidewall oxide films 41P are formed on the surface of the gate insulation film 4P in contact with the opposite sidewalls of the gate electrode 5P in such a manner as to sandwich the gate electrode 5P therebetween.

Source and drain diffusion layers 6P serving as a source region or a drain region have a predetermined depth from the main surface 1PS of the silicon substrate 1P. Each of the source and drain diffusion layers 6P is in contact with the inner wall oxide film 11P and extends nearly to a position immediately under an end of the gate insulation film 4P. LDD (Lightly Doped Drain) layers 42P of the same conductivity type as the source and drain diffusion layers 6P and having an impurity concentration lower than that of the source and drain diffusion layers 6P have a predetermined depth from the main surface 1PS of the silicon substrate 1P. Each of the LDD layers 42P is in contact with its associated source and drain diffusion layer 6P and extends nearly to a position immediately under an end of the gate electrode 5P.

A prior art method of fabricating the MOSFET having the trench-type isolation 59P is described below with reference to FIGS. 44 through 47.

First, a silicon oxide film 7P is formed on the main surface 1PS of the silicon substrate 1P, and a silicon nitride film 8P is formed on the silicon oxide film 7P. Using a photolithographic pattern as a mask, sequentially patterning the silicon nitride film 8P and the silicon oxide film 7P forms the trenches 2P in the silicon substrate 1P (See FIG. 44).

Heat treatment is performed on the silicon substrate 1P shown in FIG. 44 to thermally oxidize the inner wall and bottom faces 2PW and 2PB of the trenches 2P, thereby forming inner wall oxide films 111P. Thereafter, a film formation process which performs etching and deposition at the same time, for example, an HDP (High Density Plasma)-CVD (Chemical Vapor Deposition) process is used to form the silicon oxide 31P on the surface 8PS of the silicon nitride film 8P, on the inner wall and bottom faces 111PW and 111PB of the inner wall oxide films 111P and on parts of the silicon oxide film 7P and silicon nitride film 8P which define the inner wall faces 2PW of the trenches 2P, thereby filling the trenches 2 with the silicon oxide 31P (See FIG. 45).

The silicon oxide 31P overlying the surface 8PS of the silicon nitride film 8P is removed by the CMP (Chemical Mechanical Polishing) process using the silicon nitride film 8P as a stopper film (planarization using the CMP process). After the planarization step, a silicon oxide 32P is left only inside the trenches 2P (See FIG. 46).

The silicon nitride film 8P is removed, and thereafter the silicon oxide film 7P is removed using hydrofluoric acid. This completes the trench-type isolations 59P each comprised of the inner oxide film 11P and the silicon oxide 3P (See FIG. 47).

A first silicon oxide film and a polycrystalline silicon film are formed on the main surface 1PS in the active region 30P. The polycrystalline silicon film is patterned to form the gate electrode 5P.

Then, ion implantation into the main surface 1PS forms diffusion layers (which serve as the LDD layers 42P later) having a predetermined impurity concentration.

A second silicon oxide film is formed by the CVD process to cover the main surface 1PS of the silicon substrate 1P. Anisotropically etching the first and second silicon oxide films forms the gate insulation film 4P and the sidewall oxide films 41P.

Implanting ions again into the main surface 1PS forms the source and drain diffusion layers 6P. In this ion implantation step, the diffusion layers formed by the preceding ion implantation step are formed into the LDD layers 42P having the impurity concentration lower than that of the source and drain diffusion layers 6P (See FIG. 42). The MOSFET shown in FIG. 42 is completed through the above described steps. The illustration and description of the subsequent steps of forming an interlayer insulation film, forming source and drain electrodes to be connected to the source and drain diffusion layers 6P and the like are dispensed with.

The prior art semiconductor device having the trench-type isolation presents problems to be described below.

(i) Each of the trenches 2P is filled with the isolation 59P comprised of the silicon oxide 3P and the inner wall oxide film (silicon oxide film) 11P. These silicon oxides differ in thermal expansion coefficient from the silicon substrate 1P. When heat treatment steps, for example, the step of forming the gate oxide film 4P by thermal oxidation and the step of heat treatment (annealing) after ion implantation follow the step of forming the isolations 59P, the above described difference in thermal expansion coefficient induces stresses at the interface between the trenches 2P and the isolations 59P. The stresses are prone to cause crystal defects at the interface and inside the silicon substrate 1P.

This is problematic in that a junction leakage current increases in the source and drain diffusion layers 6P. Additionally, since the gate insulation film 4P formed where crystal defects are present is liable to be thinner than a predetermined thickness, the semiconductor device fails to provide a predetermined operating characteristic, resulting in low reliability thereof. Consequently, the yield of semiconductor devices decreases.

(ii) Another problem is that the hydrofluoric acid for removal of the silicon oxide film 7P also etches away end portions 59PE of the isolations 59P, as shown in FIG. 47. This can cause the end portions 59PE to have depressions lower in level than the main surface 1PS of the silicon substrate 1P (See FIGS. 47 and 48).

When a predetermined voltage is applied to the gate electrode 5P, an electric field from the gate electrode 5P concentrates on the silicon substrate 1P adjacent to the end portions 59PE where the gate insulation film 4P and the gate electrode 5P are formed on the depressions across the isolations 59P. Such electric field concentration decreases the potential of the silicon substrate 1P adjacent to the end portions 59PE to cause a drain current (leakage current) of the MOSFET to start flowing on a threshold voltage lower than a predetermined threshold voltage, as indicated by the curve β of FIG. 48 which shows a characteristics of the MOSFET. As a result, a hump resulting from the leakage current is observed in the characteristic curve of FIG. 48.

In this manner, the prior art semiconductor device or integrated circuit having the trench-type isolations 59 is disadvantageous in failing to provide a predetermined operating characteristic because of the end portions 59PE depressed during the formation of the isolations 59P. This induces the problem of the decrease in the yield of semiconductor devices.

### SUMMARY OF THE INVENTION

According to a first aspect of the present invention, a semiconductor device comprises: a silicon substrate; a trench extending a predetermined depth from a main surface of the silicon substrate inwardly of the silicon substrate and defining an isolation region in the silicon substrate; and a silicon oxy-nitride formed in the trench, wherein an end portion of the silicon oxy-nitride along an opening of the trench is located at a higher level than the main surface of the silicon substrate.

Preferably, according to a second aspect of the present invention, in the semiconductor device of the first aspect, the silicon oxy-nitride fills the trench; and the silicon oxy-nitride has a surface of a height increasing from the end portion thereof toward a central portion thereof.

Preferably, according to a third aspect of the present invention, in the semiconductor device of the second aspect, the silicon oxy-nitride is formed on inner wall faces and a bottom face of the trench.

Preferably, according to a fourth aspect of the present invention, the semiconductor device of the second aspect further comprises: a silicon oxide film formed on inner wall faces and a bottom face of the trench, wherein the silicon oxy-nitride is formed on inner wall faces and a bottom face of the silicon oxide film along the inner wall faces and the bottom face of the trench, and wherein an end portion of the silicon oxide film along the opening of the trench is substantially level with the main surface of the silicon substrate.

Preferably, according to a fifth aspect of the present invention, in the semiconductor device of the first aspect, the silicon oxy-nitride is formed along inner wall faces and a bottom face of the trench and does not fill the trench. The semiconductor device further comprises a silicon oxide formed on a surface of the silicon oxy-nitride to fill the trench.

Preferably, according to a sixth aspect of the present invention, in the semiconductor device of the fifth aspect, the silicon oxy-nitride is formed on the inner wall faces and the bottom face of the trench.

Preferably, according to a seventh aspect of the present invention, the semiconductor device of the fifth aspect further comprises a silicon oxide film formed on the inner wall faces and the bottom face of the trench and in contact with the silicon oxynitride, wherein an end portion of the silicon oxide film along the opening of the trench is substantially level with the main surface of the silicon substrate.

According to an eighth aspect of the present invention, a method of fabricating a semiconductor device comprises the steps of: (a) preparing a silicon substrate to form a first silicon oxide film and a stopper film including at least a silicon nitride film in the order named on a main surface of the silicon substrate; (b) etching a portion resulting from the step (a) which extends a predetermined depth from a predetermined region of a surface of the stopper film inwardly of the silicon substrate to form a trench defining an isolation region and an active region other than the isolation region in the silicon substrate; (c) forming a silicon oxy-nitride on the surface of the stopper film and along the inside of the trench; (d) removing a film formed on the surface of the stopper film by a CMP process; and (e) removing the stopper film and thereafter removing the first silicon oxide film by etching using hydrofluoric acid.

Preferably, according to a ninth aspect of the present invention, in the method of the eighth aspect, the step (c) comprises the step of forming the silicon oxy-nitride on the surface of the stopper film and on inner wall faces and a bottom face of the trench to fill the trench with the silicon oxy-nitride up to at least the same level as the surface of the stopper film.

Preferably, according to a tenth aspect of the present invention, in the method of the eighth aspect, the step (c) comprises the steps of: forming a second silicon oxide film on at least parts of the silicon substrate which are exposed at inner wall faces and a bottom face of the trench; and forming the silicon oxy-nitride over the surface of the stopper film and over the inner wall faces and the bottom face of the trench to fill the trench with the silicon oxy-nitride up to at least the same level as the surface of the stopper film.

Preferably, according to an eleventh aspect of the present invention, in the method of the eighth aspect, the step (c) comprises the steps of: forming the silicon oxynitride on at least inner wall faces and a bottom face of the trench; and forming a silicon oxide over the surface of the stopper film and on inner wall faces and a bottom face of the silicon oxy-nitride along the inner wall faces and the bottom face of the trench to fill the trench with the silicon oxide up to at least the same level as the surface of the stopper film.

Preferably, according to a twelfth aspect of the present invention, in the method of the eighth aspect, the step (c) comprises the steps of: forming a second silicon oxide film on at least parts of the silicon substrate which are exposed at inner wall faces and a bottom face of the trench; forming the silicon oxy-nitride over the surface of the stopper film and over the inner wall faces and the bottom face of the trench; and forming a silicon oxide on a surface of the silicon oxy-nitride to fill the trench with the silicon oxide up to at least the same level as the surface of the stopper film.

Preferably, according to a thirteenth aspect of the present invention, in the method of the tenth or twelfth aspect, the second silicon oxide film is formed by thermally oxidizing the inner wall faces and the bottom face of the trench.

Preferably, according to a fourteenth aspect of the present invention, in the method of the tenth or twelfth aspect, the second silicon oxide film is formed by a CVD process.

(1) In accordance with the first aspect of the present invention, since the end portion of the silicon oxy-nitride is located at a higher level than the main surface of the silicon substrate, a trench-type isolation comprising the silicon oxy-nitride has no depressions (lower than the main surface of the silicon substrate) at the end portion thereof. Then, when a gate insulation film and a gate electrode of a MOSFET are formed across the silicon oxy-nitride over the silicon oxy-nitride and the a predetermined voltage is applied to the gate electrode, no electric field is concentrated on the silicon substrate adjacent to the opening of the trench. This prevents an unsatisfactory characteristic of the semiconductor device resulting from the concentration of the electric field, for example, a source-drain leakage current in the MOSFET. Therefore, according to the first aspect of the present invention, the semiconductor device reliably accomplishes a predetermined operating characteristic.

(2) In accordance with the second aspect of the present invention, since the surface of the silicon oxy-nitride has a height increasing from the end portion thereof toward the center thereof, the entire silicon oxy-nitride is not depressed. This provides the effect (1) more reliably.

(3) In accordance with the third aspect of the present invention, the trench is completely filled with only the silicon oxy-nitride, and the entire silicon oxy-nitride is not depressed. This provides an effect similar to the effect (2).

(4-1) In accordance with the fourth aspect of the present invention, the trench is completely filled with a trench-type isolation comprising the silicon oxide film and the silicon oxy-nitride, and yet the end portion of the silicon oxide film is substantially level with the main surface of the silicon substrate. Thus, the entire trench-type isolation is not depressed. This provides an effect similar to the effect (2).

(4-2) In particular, in accordance with the fourth aspect of the present invention, the silicon oxide film is provided between the silicon oxy-nitride and the inner wall and bottom faces of the trench, to reduce the interface state of the trench and the isolation. This sufficiently suppresses a leakage current resulting from the interface state to provide the trench-type isolation which can exhibit a reliable isolation characteristic. Therefore, according to the fourth aspect of the present invention, the semiconductor device can reliably accomplish the predetermined characteristic.

(5) In accordance with the fifth aspect of the present invention, since the silicon oxy-nitride is formed along the inner wall and bottom faces of the trench, an effect similar to the effect (1) is provided.

(6) In accordance with the sixth aspect of the present invention, the silicon oxynitride is formed on the inner wall and bottom faces of the trench. Thus, the semiconductor device according to the sixth aspect of the present invention has no depressions at least in the end portion of the trench-type isolation. This provides an effect similar to the effect (1).

(7) In accordance with the seventh aspect of the present invention, the silicon oxide film formed on the inner wall and bottom faces of the trench and the silicon oxynitride formed in contact with the silicon oxide film are provided in the trench, and yet the end portion of the silicon oxide film is substantially level with the main surface of the silicon substrate. Thus, the semiconductor device according to the seventh aspect of the preset invention has no depressions at least in the end portion of the trench-type isolation. This provides an effect similar to the effect (1).

(8-1) In accordance with the eighth aspect of the present invention, the silicon oxy-nitride is formed on the surface of the stopper film and along the inside of the trench in the step (c). Since the silicon oxy-nitride is approximately equal in thermal expansion coefficient to silicon, stresses resulting from the difference in thermal expansion coefficient between the silicon and the silicon oxy-nitride are reduced in the heat treatment step after the formation of the silicon oxy-nitride. This effectively suppresses crystal defects induced by the stresses in the silicon substrate.

Therefore, the semiconductor device fabricated according to the eighth aspect of the present invention has no changes in operating characteristic due to the crystal defects and reliably accomplishes the predetermined operating characteristic. In other words, the semiconductor device fabricated according to the eighth aspect of the present invention is higher in reliability and yield than a semiconductor device fabricated by a conventional method.

(8-2) Since hydrofluoric acid has a silicon oxy-nitride etch rate which is lower than a silicon oxide etch rate, the silicon oxy-nitride is difficult to etch away when the first silicon oxide film is removed by etching using the hydrofluoric acid in the step (e). As a result, the silicon oxy-nitride left along the inside of the trench after the step (d) has a portion located at a higher level than the main surface of the silicon substrate after the step (e). Thus, according to the eighth aspect of the present invention, the semiconductor device is fabricated wherein at least the silicon oxy-nitride in the trench-type isolation has no depressions.

In other words, the use of an etch rate difference (etch selectivity) provided by the hydrofluoric acid between the silicon oxide and the silicon oxy-nitride and the suitable setting of the thicknesses of the first silicon oxide film and the stopper film allow the silicon oxy-nitride to be left with a portion located at a higher level than the main surface of the silicon substrate after the step (e).

Therefore, the method according to the eighth aspect of the present invention can fabricate the semiconductor device which has no changes (See the effect (1)) in operating characteristic due to the depressions and reliably accomplishes the predetermined operating characteristic. In other words, this method can fabricate the semiconductor device which is higher in reliability and yield than the semiconductor device fabricated by the conventional method.

(9) In accordance with the ninth aspect of the present invention, the trench-type isolation is formed of only the silicon oxy-nitride in the step (c). This provides an effect similar to the effect (8-1).

In particular, according to the ninth aspect of the present invention, the silicon oxy-nitride which fills the trench up to at least the same level as the surface of the stopper film in the step (c) has a surface located at a higher position than the main surface of the silicon substrate. Yet, the trench-type isolation comprised of only the silicon oxy-nitride as above described has an entire surface located at a higher position than the main surface of the silicon substrate. This ensures the effect (8-2).

(10-1) In accordance with the tenth aspect of the present invention, since the trench-type isolation comprises the silicon oxy-nitride, the method provides an effect similar to the effect (8-1).

In particular, according to the tenth aspect of the present invention, the second silicon oxide film which is formed thin between the trench and the silicon oxy-nitride is not excessively etched away at its end portion by the hydrofluoric acid in the step (e). Thus, the end portion of the second silicon oxide film may be substantially level with the main surface of the silicon substrate. Further, since the silicon oxy-nitride formed over the inner wall and bottom faces of the trench fills up the trench, the substantially entire surface of the trench-type isolation may be formed at a higher level than the main surface of the silicon substrate. This ensures the effect (8-2).

(10-2) Additionally, according to the tenth aspect of the present invention, the second silicon oxide film is formed on at least parts of the silicon substrate which are exposed at the inner wall and bottom faces of the trench in the step (c). Thus, the method can fabricate the semiconductor device which exhibits the effect (4-2).

(11) In accordance with the eleventh aspect of the present invention, the silicon oxy-nitride is formed on the inner wall and bottom faces of the trench in the step (c). This provides effects similar to the effects (8-1) and (8-2).

(12) In accordance with the twelfth aspect of the present invention, the silicon oxy-nitride is formed along the inside of the trench in the step (c). This provides effects similar to the effects (8-1) and (8-2).

Additionally, the second silicon oxide film is formed on at least parts of the silicon substrate which are exposed at the inner wall and bottom faces of the trench in the step (c). Thus, the method can fabricate the semiconductor device which exhibits an effect similar to the effect (10-2), that is, the effect (4-2).

(13) In accordance with the thirteenth aspect of the present invention, the second silicon oxide film is formed by thermally oxidizing the inner wall and bottom faces of the trench. This formation process causes the end portion of the active region adjacent to the opening of the trench to be formed into a rounded configuration. Thus, even if the end portion of the trench-type isolation is depressed, the semiconductor device fabricated according to the thirteenth aspect of the present invention can more sufficiently alleviate the electric field concentration (See the effect (1)) on the end portion of the active region than a semiconductor device having the conventional trench-type isolation. Therefore, the method can fabricate the semiconductor device which provides the effect (1).

(14) In accordance with the fourteenth aspect of the present invention, the second silicon oxide film is formed by the CVD process, which is advantageous in precluding the reduction in area of the active region as is caused when the second silicon oxide film is formed by the thermal oxidation process. Then, a channel width is not reduced when a MOSFET is formed in the active region. Therefore, the method can fabricate the MOSFET which suppresses the reduction in current driving capability.

It is therefore a primary object of the present invention to provide a trench-type isolation having no depressions and to provide a semiconductor device having such a trench-type isolation to ensure a predetermined operating characteristic thereof.

It is another object of the present invention to provide a semiconductor device which reduces crystal defects induced by stresses resulting from the difference in thermal expansion coefficient between a silicon substrate and a trench-type isolation to ensure a predetermined operating characteristic thereof, as well as achieving the primary object.

It is still another object of the present invention to provide a method of fabricating a semiconductor device which accomplishes a high yield, as well as achieving the above described objects.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 are schematic vertical sectional views of a semiconductor device according to a first preferred embodiment of the present invention;

FIGS. 3 through 8 are vertical sectional views of the semiconductor device in respective steps of a method of fabricating the semiconductor device according to the first preferred embodiment;

FIGS. 9 and 10 are schematic vertical sectional views of the semiconductor device according to a second preferred embodiment of the present invention;

FIGS. 11 through 15 are vertical sectional views of the semiconductor device in respective steps of the method of fabricating the semiconductor device according to the second preferred embodiment;

FIG. 16 is a schematic vertical sectional view of the semiconductor device according to the second preferred embodiment;

FIGS. 17 through 20 are vertical sectional views of the semiconductor device in respective steps of the method of fabricating the semiconductor device according to a first modification of the second preferred embodiment;

FIGS. 21 and 22 are schematic vertical sectional views of the semiconductor device according to a third preferred embodiment of the present invention;

FIGS. 23 through 27 are vertical sectional views of the semiconductor device in respective steps of the method of fabricating the semiconductor device according to the third preferred embodiment;

FIGS. 28 and 29 are schematic vertical sectional views of the semiconductor device according to a fourth preferred embodiment of the present invention;

FIGS. 30 through 35 are vertical sectional views of the semiconductor device in respective steps of the method of fabricating the semiconductor device according to the fourth preferred embodiment;

FIGS. 36 through 40 are vertical sectional views of the semiconductor device in respective steps of the method of fabricating the semiconductor device according to a first modification of the fourth preferred embodiment;

FIG. 41 is a schematic vertical sectional view of the semiconductor device according to an application of the first preferred embodiment;

FIGS. 42 and 43 are schematic vertical sectional views of a prior art semiconductor device;

FIGS. 44 through 47 are vertical sectional views of the prior art semiconductor device in respective steps of a method of fabricating the prior art semiconductor device; and

FIG. 48 shows an operating characteristic of the prior art semiconductor device.

### DESCRIPTION OF THE PREFERRED EMBODIMENTS

A semiconductor device will now be described according to first to fourth preferred embodiments of the present invention. Although a MOSFET is used herein as an example of the semiconductor device, it will become apparent from the ensuing specification that a trench-isolated structure and a method of fabricating the same which are features of the present invention are also applicable to other semiconductor devices such as a bipolar transistor and a DRAM (Dynamic Random Access Memory) to be described later.

(First Preferred Embodiment)

FIG. 1 is a schematic vertical sectional view of a MOSFET according to the first preferred embodiment of the present invention. The basic structure of the MOSFET of the first preferred embodiment will be described with reference to FIG. 1.

As shown in FIG. 1, the MOSFET comprises a semiconductor substrate 1 (also referred to hereinafter as a “silicon substrate 1”) made of, for example, single crystalline silicon. Trenches 2 are formed which have a predetermined depth from a main surface 1S of the semiconductor substrate 1 toward the inside thereof. The trenches 2 define an isolation region 20 inside the semiconductor substrate 1. The isolation region 20 shall not only mean a two-dimensional region extending in the plane of the main surface 1S of the semiconductor substrate 1 but also include a three-dimensional region extending also in a direction perpendicular to the main surface 1S of the semiconductor substrate 1. Thus, the semiconductor substrate 1 is divided into two regions: the isolation region 20 and an active region 30 which is a three-dimensional region other than the isolation region 20.

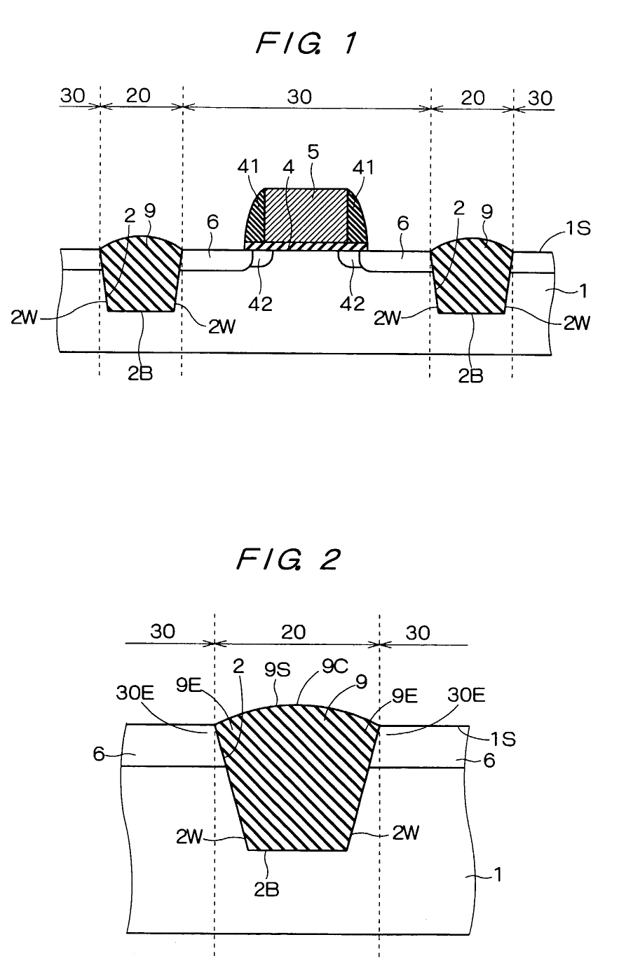

The structure of the isolation region 20 which is a feature of the MOSFET of the present invention is described below with reference to FIG. 2. FIG. 2 is an enlarged view of the isolation region 20 of FIG. 1 and its surrounding parts.

As depicted in FIG. 2, a silicon oxy-nitride 9 is formed on inner wall faces 2W and a bottom face 2B of a trench 2 to completely fill the trench 2 (conversely, the trench 2 is completely filled with only the silicon oxy-nitride 9). In particular, the ratio between compositions of the silicon oxy-nitride 9 is set so that the silicon oxy-nitride 9 is approximately equal in thermal expansion coefficient to silicon which is the material of the semiconductor substrate 1.

Further, in the MOSFET, end portions 9E of the silicon oxy-nitride 9 which are adjacent to the edges thereof along the opening of the trench 2 are located at a higher level than the main surface 1S of the semiconductor substrate 1 (although the edges of the silicon oxy-nitride 9 are substantially level with the main surface 1S of the semiconductor substrate 1). Additionally, the surface 9S of the silicon oxy-nitride 9 increases in height from the end portions 9E toward a central portion 9C of the surface 9S.

The silicon oxy-nitride 9 is also referred to hereinafter as a “(trench-type or wedge-type) isolation 9.”

Referring again to FIG. 1, a gate insulation film 4 (also referred to hereinafter as a “gate oxide film 4”) made of, for example, silicon oxide is formed in a predetermined region on the main surface 1S in the active region 30. Sidewall oxide films 41 are formed on the surface of the gate insulation film 4 within a predetermined distance from the opposite edges of the gate insulation film 4. A gate electrode 5 is formed in contact with the surface of the gate insulation film 4 and the inner sidewalls of the sidewall oxide films 41.

Source and drain diffusion layers 6 have a predetermined depth from the main surface 1S of the silicon substrate 1. Each of the source and drain diffusion layers 6 is in contact with the silicon oxy-nitride 9 and extends nearly to a position immediately under an end of the gate insulation film 4. Diffusion layers or LDD (Lightly Doped Drain) layers 42 are of the same conductivity type as the source and drain diffusion layers 6 and have an impurity concentration lower than that of the source and drain diffusion layers 6. Each of the diffusion layers or LDD layers 42 extends from an end of its associated source and drain diffusion layer 6 which is closer to the gate insulation film 4 nearly to a position immediately under an end of the gate electrode 5.

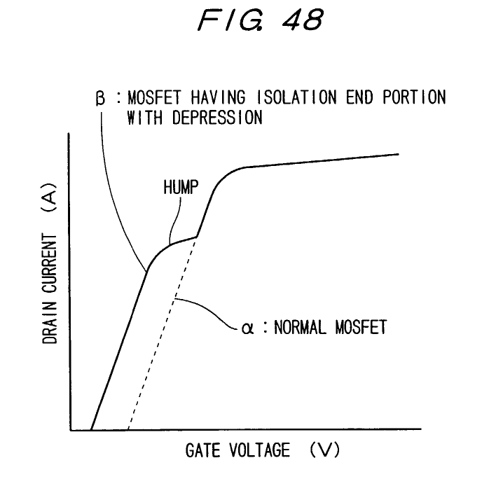

As above described, the isolations 9 of the MOSFET of the first preferred embodiment do not have a depression which has been formed in the end portions 59PE of the prior art trench-type isolations 59P of FIG. 43. Thus, no electric field is concentrated on portions adjacent to end portions 30E of the active region 30 where the gate insulation film 4 and the gate electrode 5 are formed across the isolations 9 on the surfaces 9S of the isolations 9 when a predetermined voltage is applied to the gate electrode 5. Therefore, the MOSFET of the first preferred embodiment is effective in preventing an unsatisfactory characteristic resulting from the electric field concentration, for example, a source-drain leakage current (See the hump of FIG. 48) to consequently accomplish a high yield of MOSFETs.

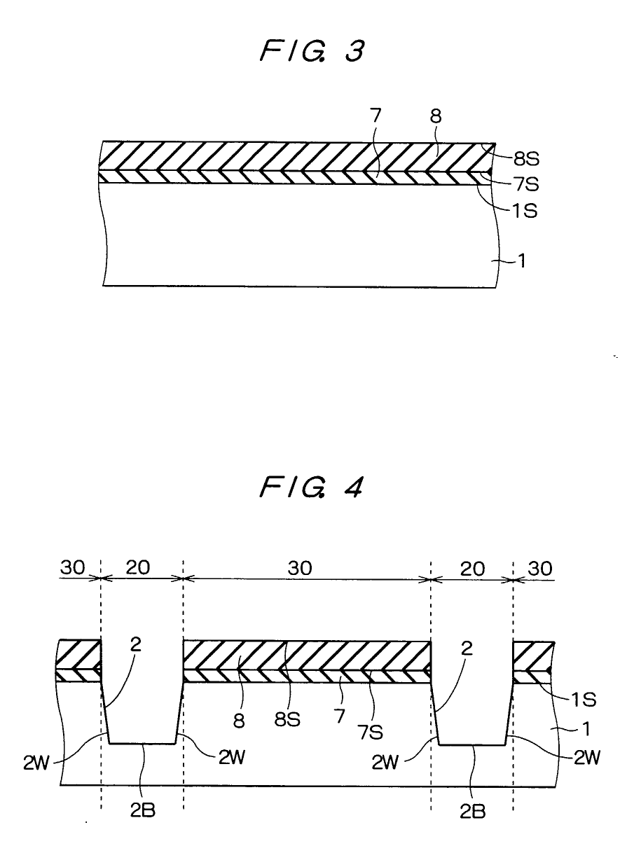

A method of fabricating the MOSFET will now be described with reference to FIGS. 3 through 8 which are schematic vertical sectional views of the MOSFET in respective fabrication steps.

(First Step)

As shown in FIG. 3, a silicon oxide film (first silicon oxide film) 7 having a thickness on the order of 5 to 30 nm is formed on the main surface 1S of the silicon substrate 1 by thermal oxidation. Then, a silicon nitride film 8 having a thickness on the order of 100 to 300 nm is formed on the surface 7S of the silicon oxide film 7.

The silicon nitride film 8 functions as a stopper film in a planarization step using the CMP (Chemical Mechanical Polishing) process in a fourth step to be described later, and is thus also referred to as a “stopper film 8.”

(Second Step)

Referring to FIG. 4, the silicon nitride film 8, the silicon oxide film 7 and parts of the silicon substrate 1 (parts having a depth of 100 to 500 nm from the surface 1S) are anisotropically etched from predetermined regions lying in the plane of the surface 8S of the silicon nitride film 8 and to serve as the isolation region 20 toward the inside of the silicon substrate 1, using a photolithographic pattern as a mask. This forms the trenches 2 having the predetermined depth. Such formation of the trenches 2 divides the silicon substrate 1 into the isolation region 20 and the active region 30.

Although various processes including the removal of the stopper film 8 and the silicon oxide film 7 are performed on the trenches 2 of FIG. 4 in subsequent fabrication steps to form the trenches 2 of FIG. 1, the term “trench 2” is used so far as it is based on the structure formed in the second step.

(Third Step)

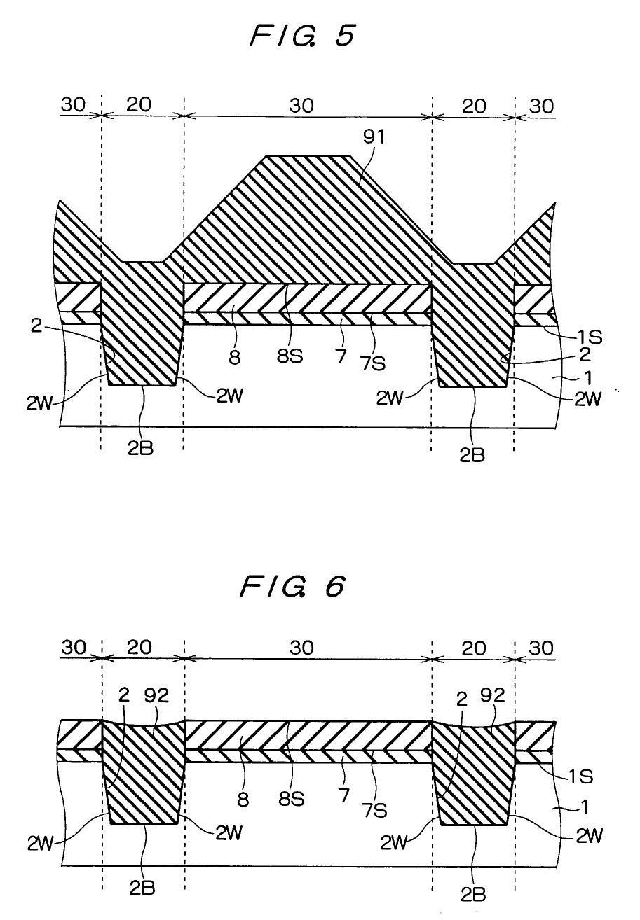

Referring to FIG. 5, a film formation process which performs etching and deposition at the same time, for example, the HDP (High Density Plasma)-CVD (Chemical Vapor Deposition) process is used to form a silicon oxy-nitride 91 having a thickness on the order of 200 to 700 nm along the surface 8S of the stopper film 8 and the inside of the trenches 2.

In the MOSFET of the first preferred embodiment, in particular, the silicon oxy-nitride 91 is formed on the surface 8S of the stopper film 8 and on the inner wall and bottom faces 2W and 2B of the trenches 2 to fill the trenches 2 up to at least the same level as the surface 8S.

A distinction is made hereinafter between the silicon oxy-nitride 91 present in the isolation region 20 which is referred to as a “buried oxy-nitride 91” and the silicon oxy-nitride 91 present in the active region 30 which is referred to as a “silicon oxy-nitride film 91,” as particularly required.

Other film formation processes may be used to form the silicon oxy-nitride 91. However, the film formation process which performs etching and deposition at the same time such as the HDP-CVD process is advantageous in producing few seams (key-hole shaped voids) to completely fill the trenches 2 with the silicon oxy-nitride 91.

The film formation process which performs etching and deposition at the same time is described briefly below. As shown in FIG. 5, such a film formation process provides the silicon oxy-nitride 91 on the surface 8S of the silicon nitride film 8 (that is, the silicon oxy-nitride film 91) which has a sectional configuration of a triangular or trapezoidal protrusion angled at about 45 degrees with respect to the surface 8S. The silicon oxy-nitride film 91 is trapezoidal when the active region 30 has a width greater than generally twice the thickness of the silicon oxy-nitride film 91. The maximum thickness of the silicon oxy-nitride film 91 is equal to a distance from the bottom face 2B of the trenches 2 to an exposed surface of the buried oxy-nitride 91.

(Fourth Step)

The silicon oxy-nitride film 91 on the surface 8S of the stopper film 8 is removed by the CMP process using the silicon nitride film 8 as the stopper film (See FIG. 6). In this step, the buried oxy-nitride 91 is also removed to a level similar to the surface 8S of the stopper film 8 so that a silicon oxy-nitride 92 (also referred to hereinafter as a “buried oxy-nitride 92”) shown in FIG. 6 is left in each of the trenches 2.

The structure of the film (formed in the first step) used as the mask for the formation of the trenches 2 or the isolation region 20 may include a structure comprising a film of polycrystalline silicon between the silicon oxide film 7 and the silicon nitride film 8 for alleviating the stresses therebetween, and a structure comprising a film, e.g. another silicon oxide film, formed on the silicon nitride film 8 for protecting the silicon nitride film 8 during the anisotropic etching in the step of forming the trenches 2, as well as a multilayer structure of FIG. 3 including the silicon oxide film 7 and the silicon nitride film 8, so long as the silicon nitride film 8 is used as the stopper film for polishing using the CMP process. In these cases, a multilayer film formed on the surface 7S of the silicon oxide film 7 and comprising at least the silicon nitride film 8 may be referred to as a “stopper film.” The same is true for the fabrication method of the second to fourth preferred embodiments to be described later.

(Fifth Step)

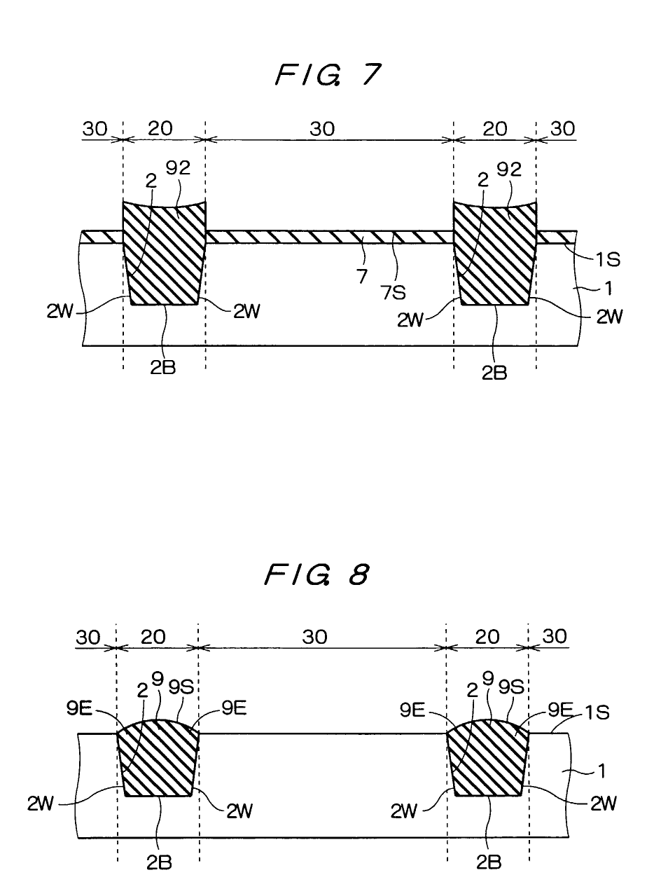

The silicon nitride film 8 is removed using phosphoric acid at elevated temperatures (See FIG. 7). At this time, the buried oxy-nitride 92 which has a lower etch rate provided by the phosphoric acid at elevated temperatures than does silicon nitride is hardly etched away.

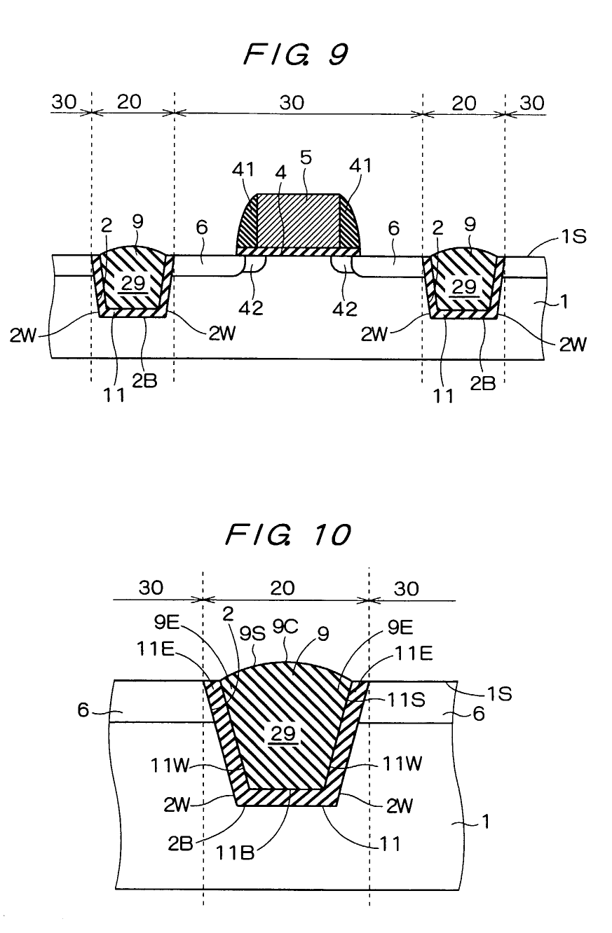

Subsequently, the silicon oxide film 7 is removed by wet etching using hydrofluoric acid (See FIG. 8). In this wet etching step, the buried oxy-nitride 92 shown in FIG. 7 is partially etched. The (trench-type or wedge-type) isolations 9 each comprising the silicon oxy-nitride 9 (also referred to hereinafter a “buried oxy-nitride 9”) formed in the trench 2 are completed, as illustrated in FIG. 8.

In particular, the buried oxy-nitride 92 which is made of silicon oxy-nitride having a lower etch rate provided by the hydrofluoric acid than does silicon oxide is etched away by a smaller amount when the wet etching using the hydrofluoric acid is performed for removal of the silicon oxide film 7. This prevents depressions in the end portions 9E of the trench-type isolations 9 along the opening of the trenches 2. Additionally, the exposed surface 9S of each isolation 9 is formed at a higher level than the surface 1S of the semiconductor substrate 1. In other words, the method of fabricating the MOSFET of the first preferred embodiment utilizes the etch rate difference (etch selectivity) provided by the hydrofluoric acid between the silicon oxide and the silicon oxy-nitride and sets the suitable thicknesses of the silicon oxide film 7 and the stopper film 8 to form the trench-type isolations 9 having the surface 9S higher in level than the surface 1S of the silicon substrate 1 even after the removal of the stopper film 8 and the silicon oxide film 7, thereby preventing the depressions in the end portions 9E of the isolations 9.

(Sixth Step)

A silicon oxide film (not shown) is formed on the entire main surface 1S of the silicon substrate 1 of FIG. 8 by thermal oxidation. Ion implantation is performed to dope the resultant structure for the formation of a well of a predetermined conductivity type and for threshold voltage control. Thereafter, the silicon oxide film is removed by wet etching using hydrofluoric acid.

Thermal oxidation of the surface 1S at a temperature of about 750° C. forms a silicon oxide film having a thickness on the order of 7 nm. A polycrystalline silicon film having a thickness of 70 nm and a tungsten silicide film having a thickness of 70 nm are formed in the order named by the CVD process to entirely cover the silicon oxide film.

A resist is formed on the surface of the tungsten silicide film and then patterned using the photolithographic technique. Using the patterned resist as a mask, the polycrystalline silicon film and the tungsten silicide film are anisotropically etched to form the gate electrode 5 shown in FIG. 1. Thereafter, the resist is removed.

Phosphorus ions are implanted into the surface 1S of the silicon substrate 1 at an energy of 30 keV and at a dose of about 1E13 cm⁻². The diffusion layers formed by this ion implantation is to serve later as the diffusion layers or LDD layers 42 of FIG. 1.

A silicon oxide film having a thickness of about 50 nm is formed to entirely cover the about 7 nm thick silicon oxide film and the gate electrode 5 which are exposed, and is anisotropically etched to form the sidewall oxide films 41 shown in FIG. 1. In this etching process, parts of the about 7 nm thick silicon oxide film on the main surface 1S which are not in contact with the gate electrode 5 and the sidewall oxide films 41 are etched away. The gate insulation film 4 of FIG. 1 is thus formed.

Arsenic ions are implanted into the main surface 1S at an energy of 30 keV and at a dose of about 2E15 cm⁻², and the silicon substrate 1 is heat treated (annealed) at a temperature of about 820° C. for about 30 minutes. This forms the source and drain diffusion layers 6 of FIG. 1. At this time, the diffusion layers formed by the previous phosphorus ion implantation and lying under the gate electrode 5 and the sidewall oxide films 41 are formed into the diffusion layers 42 of FIG. 1. The annealing may follow each of the ion implantation steps.

The MOSFET shown in FIG. 1 is completed through the above described fabrication steps. An interlayer insulation film, interconnect lines to be connected respectively to the source and drain diffusion layers 6 and the like which are added to the MOSFET of FIG. 1 and not shown will be described later with reference to an application.

According to the method of the first preferred embodiment, the silicon oxy-nitride 91 which is approximately equal in thermal expansion coefficient to the silicon substrate 1 is formed in each of the trenches 2 in the third step. This reduces the stresses at the interfaces between the isolations 9 and the trenches 2 (the interfaces between the silicon oxy-nitride and the silicon) due to the difference in thermal expansion coefficient in the subsequent steps, for example, in the steps of forming the thermally oxidized film and annealing after ion implantation, thereby effectively suppressing crystal defects induced by the stresses at the interface and inside the silicon substrate 1. In the fabrication steps of a DRAM shown in FIG. 41 to be described later, the heat treatment step after the formation of the isolations 9 may include the step of forming a capacitor insulation film 17 and reflowing interlayer insulation films 50A, 50B and 50C.

Therefore, the method of the first preferred embodiment can provide the MOSFET in which the deterioration of a junction characteristic due to the crystal defects and the deterioration of the reliability of the gate insulation film are significantly suppressed. Specifically, the method of the first preferred embodiment can fabricate the MOSFET which ensures a predetermined operating characteristic in conjunction with the above described effects of the absence of the depressions in the end portions 9E of the isolations 9, with a high yield.

A conventional structure of the semiconductor device having a trench-type isolation comprising a silicon oxy-nitride is disclosed in Japanese Patent Application Laid-Open No. P07-307382A (1995) (referred to hereinafter as Reference (1)). However, the trench-type isolation disclosed in Reference (1) differs from the trench-type isolations 9 of the first preferred embodiment in that the surface of the isolation of Reference (1) is level with the main surface of a semiconductor substrate.

Further, in the method of fabricating the isolation disclosed in Reference (1), the step of filling the trench formed in the semiconductor substrate with the silicon oxynitride is performed in such a manner that the silicon oxy-nitride is formed on the main surface of the semiconductor substrate and in the trench, with no film formed on the main surface of the semiconductor substrate. Then, in the subsequent step of removing the silicon oxy-nitride on the main surface of the semiconductor substrate (using the plasma etching process or the CMP process which are proposed as an example), the silicon oxynitride in the trench is partially removed. As a result, there is a likelihood that an end portion or a central portion of the surface of the trench-type isolation along the opening of the trench is depressed or becomes lower than the main surface of the semiconductor substrate. Therefore, the trench-type isolation and the method of fabricating the same disclosed in Reference (1) are not considered to sufficiently avoid the unsatisfactory characteristic of the semiconductor device resulting from the depressions.

In the method of fabricating the isolations 9 of the first preferred embodiment, on the other hand, the silicon oxide film 7 and the stopper film 8 are formed on the main surface 1S of the semiconductor substrate 1, and thereafter the silicon oxy-nitride 91 is formed on the surface 8S of the stopper film 8 and in the trenches 2. Thus, the surface of the buried oxy-nitride 92 does not have the depressions lower than the main surface 1S of the semiconductor substrate 1 after the polishing by the CMP process. Additionally, the surface of the buried oxy-nitride 92 which is located at a sufficiently higher level than the main surface 1S is reliably prevented from being depressed or becoming lower than the main surface 1S of the semiconductor substrate 1 after the fifth step wherein the stopper film 8 and the silicon oxide film 7 are removed using hydrofluoric acid. In such terms, the trench-type isolations 9 and the method of fabricating the same according to the first preferred embodiment may be considered to be more advantageous than the isolation and the method of fabricating the same disclosed in Reference (1).

(Second Preferred Embodiment)

The basic structure of the MOSFET according to the second preferred embodiment of the present invention will be described with reference to FIGS. 9 and 10. FIG. 9 is a schematic vertical sectional view of the MOSFET according to the second preferred embodiment of the present invention. FIG. 10 is an enlarged view of the isolation region 20 of FIG. 9 and its surrounding parts. As shown in FIGS. 9 and 10, the MOSFET of the second preferred embodiment features the structure in the trenches 2, that is, the structure of trench-type isolations 29 to be described below. Hence, this structure is mainly described, and other elements similar to those of the MOSFET of the first preferred embodiment are designated by like reference characters for reference to the description thereon in the first preferred embodiment.

As illustrated in FIGS. 9 and 10, the MOSFET of the second preferred embodiment includes a silicon oxide film 11 formed on the inner wall and bottom faces 2W and 2B of each of the trenches 2. End portions 11E of the silicon oxide film 11 along the opening of each trench 2 are substantially level with the main surface 1S of the semiconductor substrate 1.

The silicon oxy-nitride 9 is formed on inner wall faces 11W and a bottom face 11B of the silicon oxide film 11 along the inner wall and bottom faces 2W and 2B, and completely fills each trench 2. The surface 9S of the silicon oxy-nitride 9 increases in height from the end portions 9E toward the central portion 9C of the surface 9S. A structure for isolation which comprises the silicon oxide film 11 and the silicon oxy-nitride 9 that fill each trench 2 is also referred to hereinafter as a “(trench-type or wedge-type) isolation 29.”

The MOSFET of the second preferred embodiment thus comprises the trench-type isolations 29 having no depressions along the opening of the trenches 2 to prevent changes in operating characteristic due to the depressions, providing effects similar to those of the first preferred embodiment.

In particular, the MOSFET of the second preferred embodiment includes the silicon oxide film 11 between the silicon oxy-nitride 9 and the inner wall and bottom faces 2W and 2B of each trench 2 to reduce an energy state at the interfaces between the trenches 2 and the isolations 29, as compared with the MOSFET of the first preferred embodiment having the silicon oxy-nitride 9 directly formed in each trench 2. Thus, the trench-type isolations 29 sufficiently suppress a leakage current resulting from the interface state to provide a reliable isolation characteristic of the isolations. The MOSFET of the second preferred embodiment can accomplish the predetermined operating characteristic.

The method of fabricating the MOSFET according to the second preferred embodiment is described below. The method of the second preferred embodiment particularly features the process for fabricating the isolations 29. Hence, a fabrication step corresponding to the third step of the first preferred embodiment will be mainly described, with the first and second steps of the first preferred embodiment used as those of the second preferred embodiment. This shall be true for the third and fourth preferred embodiments to be described later.

(Third Step)

The silicon substrate 1 with the trenches 2 formed therein and shown in FIG. 4 is heat treated in an oxygen atmosphere at 1100° C. This thermally oxidizes parts of the silicon substrate 1 which are exposed at the inner wall and bottom faces 2W and 2B of each trench 2 to form a silicon oxide film (second silicon oxide film) 111 having a thickness of about 15 nm (See FIG. 11). The thermal oxidation process causes the interface between the semiconductor substrate 1 of silicon and the silicon oxide film 111 to be formed inwardly of the silicon substrate 1 from the inner wall and bottom faces 2W and 2B of each trench 2 shown in FIG. 4. Regarding the parts of the silicon substrate 1 which define the trenches 2, the trench defined by the surface of the silicon substrate 1 at the interface after the formation of the silicon oxide film 111 which is a thermally oxidized film is newly referred to as a “trench 2,” and parts of the surface which correspond to the inner wall faces 2W and the bottom face 2B of FIG. 4 are newly referred to as the “inner wall faces 2W of the trench 2” and the “bottom face 2B of the trench 2” respectively. The isolation region 20 is accordingly increased in area, and the active region 30 is accordingly reduced.

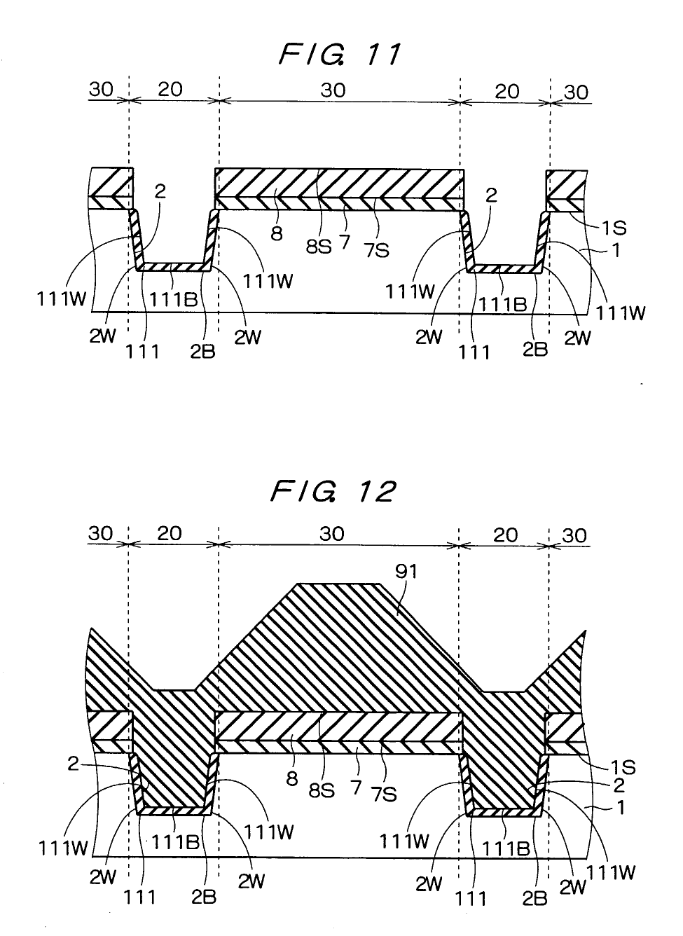

Referring to FIG. 12, the silicon oxy-nitride 91 is formed on the surface 8S of the stopper film 8 and on the inner wall and bottom faces 111W and 111B of the silicon oxide film 111 along the inner wall and bottom faces 2W and 2B of each trench 2 by using the HDP-CVD process so as to fill the trenches 2 up to at least the same level as the surface 8S.

(Fourth to Sixth Steps)

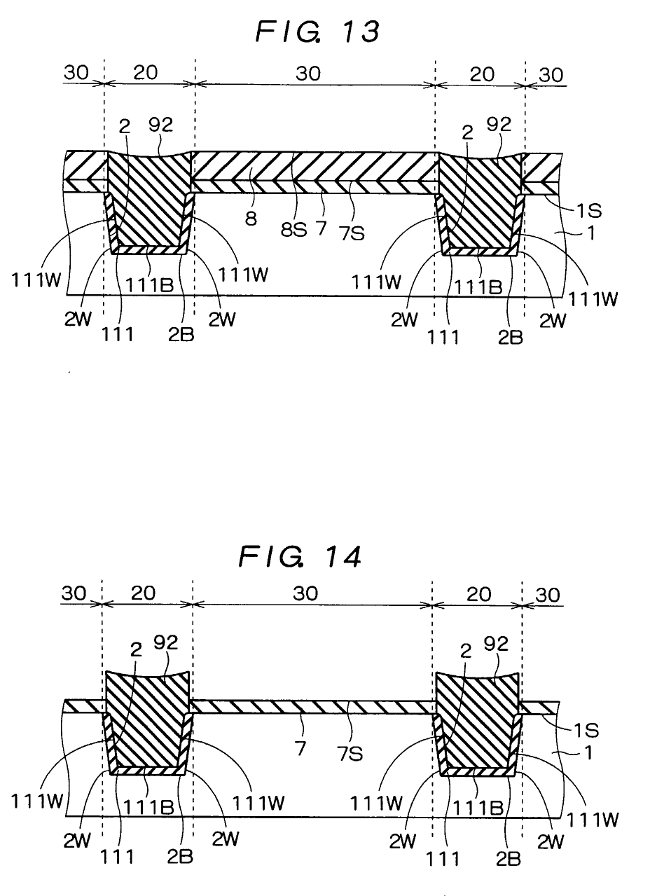

The silicon oxy-nitride film 91 on the surface 8S of the stopper film 8 is removed by the CMP process as in the fourth step of the first preferred embodiment (See FIG. 13). In this step, the buried oxy-nitride 91 of FIG. 12 is also removed to a level similar to the surface 8S of the stopper film 8 so that the silicon oxy-nitride or buried oxynitride 92 is left in each of the trenches 2.

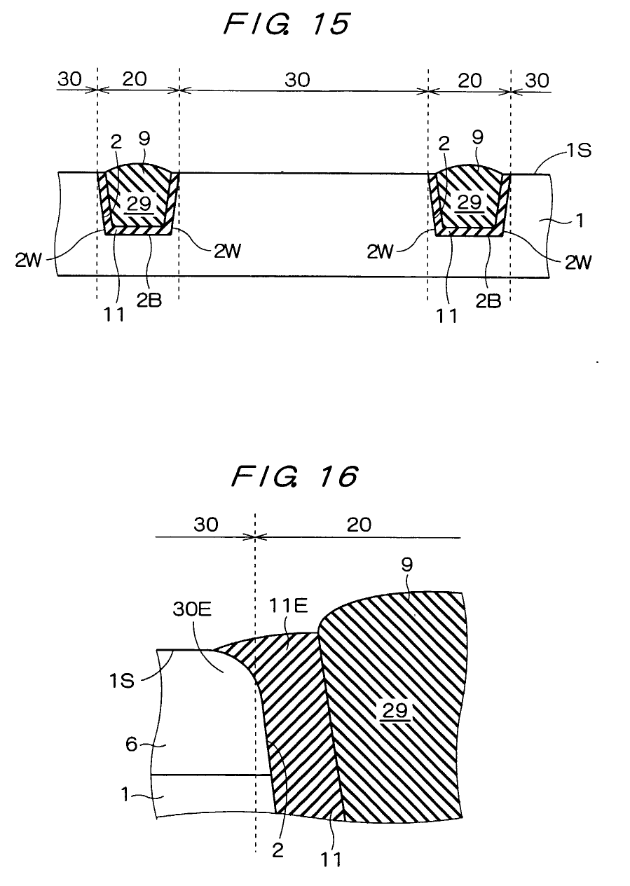

The silicon nitride film 8 is removed using phosphoric acid at elevated temperatures as in the fifth step of the first preferred embodiment (See FIG. 14). Subsequently, the silicon oxide film 7 is removed by wet etching using hydrofluoric acid (See FIG. 15). In this wet etching step, the buried oxy-nitride 92 shown in FIG. 14 is partially etched. The trench-type (wedge-type) isolations 29 each comprising the silicon oxy-nitride or buried oxy-nitride 9 and the silicon oxide film 11 formed in the trench 2 are completed, as illustrated in FIG. 15.

The MOSFET shown in FIG. 9 is completed through the fabrication step similar to the sixth step of the first preferred embodiment.

The method of the second preferred embodiment is similar to that of the first preferred embodiment in that the surface 9S of the buried oxy-nitride 9 is formed at a higher level than the surface 1S of the semiconductor substrate 1. In particular, the silicon oxide film 11 is formed thin between the trenches 2 and the silicon oxy-nitride 9 to prevent the end portions 11E of the silicon oxide film 11 (See FIG. 10) from being excessively etched away when the silicon oxide film 7 is removed using the hydrofluoric acid in the fifth step. This allows the end portions 11E to be substantially level with the main surface 1S of the semiconductor substrate 1. Therefore, the depressions are hardly formed in the entire isolations 29.

Of course, the silicon oxy-nitride 91 is buried in the trenches 2 in the third step to reduce the stresses induced in the subsequent heat treatment step.

The method of the second preferred embodiment may thus fabricate the MOSFET which is free from the depressions and the stress-induced unsatisfactory operating characteristic, with a high yield.

According to the method of the second preferred embodiment, in particular, the silicon oxide film 11 is formed by thermally oxidizing the parts of the silicon substrate 1 which are exposed at the inner wall and bottom faces 2W and 2B of the trenches 2. As shown in FIG. 16 which is an enlarged view of the boundary between the isolation region 20 and the active region 30, the end portion 30E of the active region 30 is rounded in configuration because of such formation of the silicon oxide film 11. Thus, if an end portion of the isolations 29 is depressed, the electric field applied from the gate electrode 5 to the end portion 30E of the active region 30 is alleviated when a predetermined voltage is applied to the gate electrode 5 formed across the isolations 29. Therefore, the method of the second preferred embodiment has the advantage over the prior art MOSFET in fabricating the MOSFET which suppresses the drawback (e.g., the occurrence of the hump of FIG. 48) resulting from the concentration of the electric field on the end portion 30E of the active region 30, with a high yield.

(First Modification of Second Preferred Embodiment)

Description will now be given on a modification of the method of fabricating the MOSFET shown in FIG. 9, particularly a modification of the method of fabricating the silicon oxide film 11.

(Third Step)

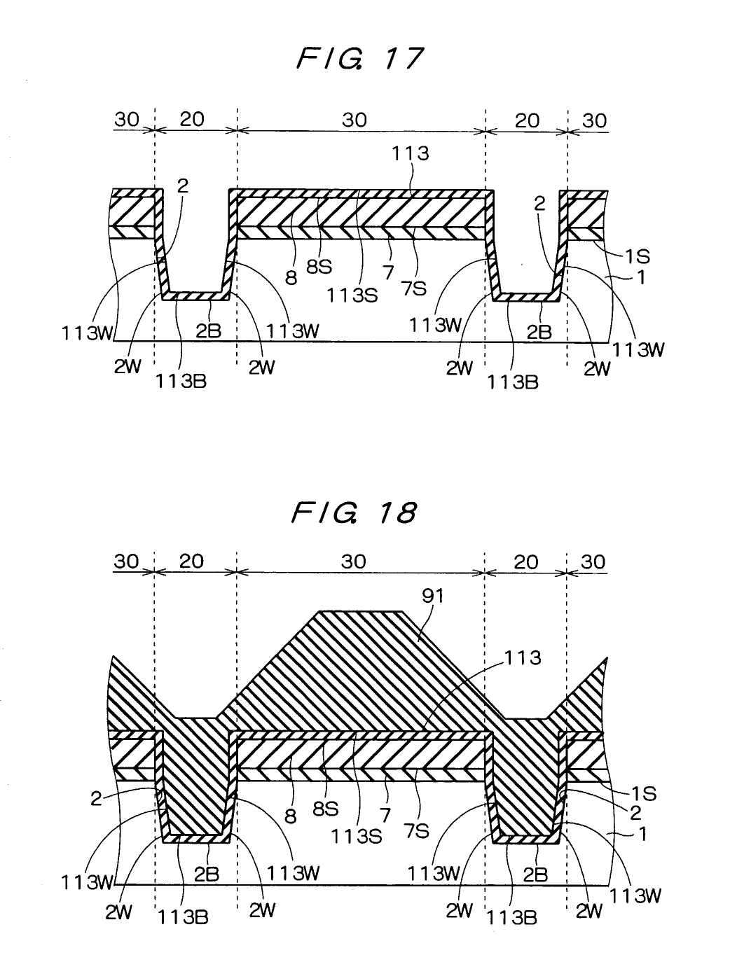

Initially, a silicon oxide film 113 having a thickness of about 15 nm is formed to entirely cover the exposed surface of the silicon substrate 1 of FIG. 4 by the CVD process (See FIG. 17). At this time, the silicon oxide film (second silicon oxide film) 113 is formed at least on parts of the silicon substrate 1 which are exposed at the inner wall and bottom faces 2W and 2B of the trenches 2.

Referring to FIG. 18, the silicon oxy-nitride 91 is formed by the HDP-CVD process over the surface 8S of the stopper film 8 and on the inner wall and bottom faces 113W and 113B of the silicon oxide film 113 along the inner wall and bottom faces 2W and 2B. That is, the silicon oxy-nitride 91 entirely covers the surface 113S of the silicon oxide film 113 and fills the trenches 2 up to at least the same level as the surface 8S of the stopper film 8.

(Fourth to Sixth Steps)

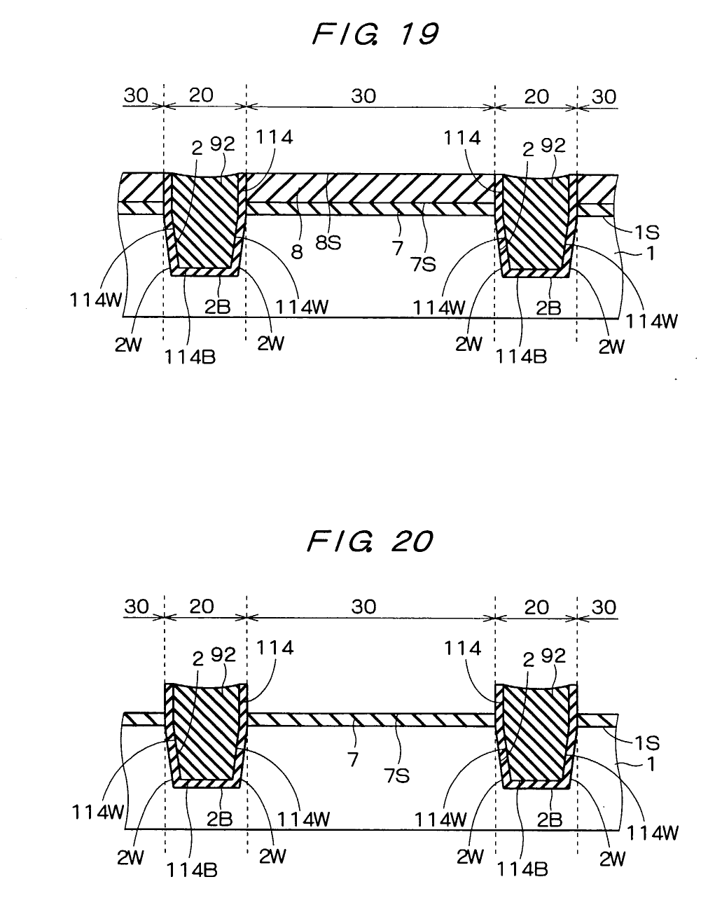

The silicon oxide film 113 and the silicon oxy-nitride film 91 serially formed on the surface 8S of the stopper film 8 are removed by the CMP process as in the fourth step of the first preferred embodiment (See FIG. 19). In this step, parts of the silicon oxide film 113 which are formed on the inner wall and bottom faces 2W and 2B of the trenches 2 are left as silicon oxide films 114, as shown in FIG. 19. The buried oxy-nitride 91 of FIG. 18 is removed to a level similar to the surface 8S so that the silicon oxy-nitride or buried oxy-nitride 92 of FIG. 19 is left in each of the trenches 2.

The silicon nitride film 8 is removed using phosphoric acid at elevated temperatures as in the fifth step of the first preferred embodiment (See FIG. 20). Subsequently, the silicon oxide film 7 is removed by wet etching using hydrofluoric acid (See FIG. 15). In this wet etching step, the buried oxy-nitride 92 and the silicon oxide film 114 shown in FIG. 20 are partially etched. The trench-type (wedge-type) isolations 29 each comprising the silicon oxy-nitride or buried oxy-nitride 9 and the silicon oxide film 11 formed in the trench 2 are completed, as shown in FIG. 15.

The MOSFET shown in FIG. 9 is completed through the fabrication step similar to the sixth step of the first preferred embodiment.

The method of the first modification of the second preferred embodiment is advantageous in that the silicon oxide film 111 formed by the CVD process prevents the reduction in the area of the active region 30, as compared with the silicon oxide film 111 formed by the thermal oxidation in the method of the second preferred embodiment. This prevents the reduction in channel width to achieve the fabrication of the MOSFET which suppresses the reduction in current driving capability.

A conventional structure of the semiconductor device having a trench-type isolation comprising a silicon oxide film formed on the inner wall and bottom faces of the trench and a silicon oxy-nitride formed on the surface of the silicon oxide film is disclosed in Japanese Patent Application Laid-Open No. P60-132341A (1985) (referred to hereinafter as Reference (2)). However, the trench-type isolation disclosed in Reference (2) differs from the trench-type isolations 29 of the second preferred embodiment and the first modification thereof in that the surface of the isolation of Reference (2) is level with the surface of the semiconductor substrate. This difference arises from the difference in basic viewpoint therebetween: the technique of Reference (2) is to form the surface of the isolation as level with the surface of the semiconductor substrate as possible, whereas the technique of the second preferred embodiment and the first modification thereof is to form the surface of the isolations 29 at a higher level than the main surface 1S of the semiconductor substrate 1.

Further, a method of fabricating the isolation disclosed in Reference (2) comprises the step of forming a silicon oxide film on the entire exposed surface of the semiconductor substrate with the trench formed therein. On the other hand, the method of the second preferred embodiment comprises the step of forming the silicon oxide film 111 only on the parts of the silicon substrate 1 which are exposed at the inner wall and bottom faces 2W and 2B of the trenches 2 as shown in FIG. 11, and the method of the first modification of the second preferred embodiment comprises the step of forming the silicon oxide film 113 on the inner wall and bottom faces 2W and 2B and on the surface 8S of the stopper film 8 over the first main surface 1S of the semiconductor substrate 1. Thus, there is a significant difference between the method of the second preferred embodiment and the first modification thereof and the method disclosed in Reference (2) in the position of the silicon oxide film formed in the trench. Furthermore, although the method disclosed in Reference (2) forms the silicon oxide film by the thermal oxidation, the method of the second preferred embodiment and the first modification thereof may select either the thermal oxidation process or the CVD process to form the silicon oxide film 111 or 113 (different, of course, in the formation position from that of Reference (2)), providing the advantage in that the fabrication method is selectable depending on existing facilities and semiconductor device types to be fabricated.

As above described, the formation of the silicon oxide film 113 (to be formed into the silicon oxide film 11 later) by the CVD process prevents the reduction in the area of the active region, as compared with the formation of the silicon oxide film in the trench by the thermal oxidation process as in Reference (2) (as well as Reference (1) and Reference (3) to be described below), leading to the fabrication of the MOSFET which can exhibit a predetermined current driving capability.

Additionally, the method disclosed in Reference (2) comprises forming the silicon oxide film (thermally oxidized film) directly on the entire surface of the semiconductor substrate with the trench formed therein and thereafter forming the silicon oxy-nitride on the surface of the silicon oxide film. This is considered to be prone to produce depressions in an end portion of the isolation when etching (dry etching and wet etching are proposed) for completion of the isolation is performed for the same reason as the method disclosed in Reference (1). Therefore, the method of the second preferred embodiment and the first modification thereof is more advantageous.

A conventional structure of the isolation comprising a silicon oxide film formed on the inner wall and bottom faces of a trench and a silicon oxy-nitride formed on the surface of the silicon oxide film (and a silicon nitride formed in the silicon oxy-nitride) is disclosed in the specification of U.S. Pat. No. 4,825,277 (referred to hereinafter as Reference (3)). However, the isolation disclosed in Reference (3) differs from the isolations 29 of the second preferred embodiment and the first modification thereof in that the surface thereof is level with the surface of the semiconductor substrate. There is a complete difference in basic viewpoint between the technique disclosed in Reference (3) and the technique of the second preferred embodiment and the first modification thereof since the technique of Reference (3), similar to that of Reference (2), is to form the surface of the isolation as level with the surface of the semiconductor substrate as possible.

Moreover, a fabrication method disclosed in Reference (3) comprises forming the silicon oxide film and the silicon oxy-nitride in the order named directly on the exposed surface of the semiconductor substrate with the trench formed therein. Thus, similar to the method disclosed in Reference (2), the method of Reference (3) fails to achieve the particular effect of the method of the second preferred embodiment and the first modification thereof that the isolation is effectively prevented from being depressed.

Reference (1) has also proposed a semiconductor device having a trench-type isolation comprising a contact layer (silicon oxide film) formed on the inner wall and bottom faces of the trench and a silicon oxy-nitride formed on the surface of the contact layer. The structure of such an isolation basically follows the structure referred to in the first preferred embodiment, and thus the description about the difference therebetween in the first preferred embodiment shall be used herein as it is.

The description about References (1) to (3) is applicable also to a trench-type isolation having a two-layer structure formed in a smaller-width trench which is proposed in Reference (4) to be described later.

(Third Preferred Embodiment)

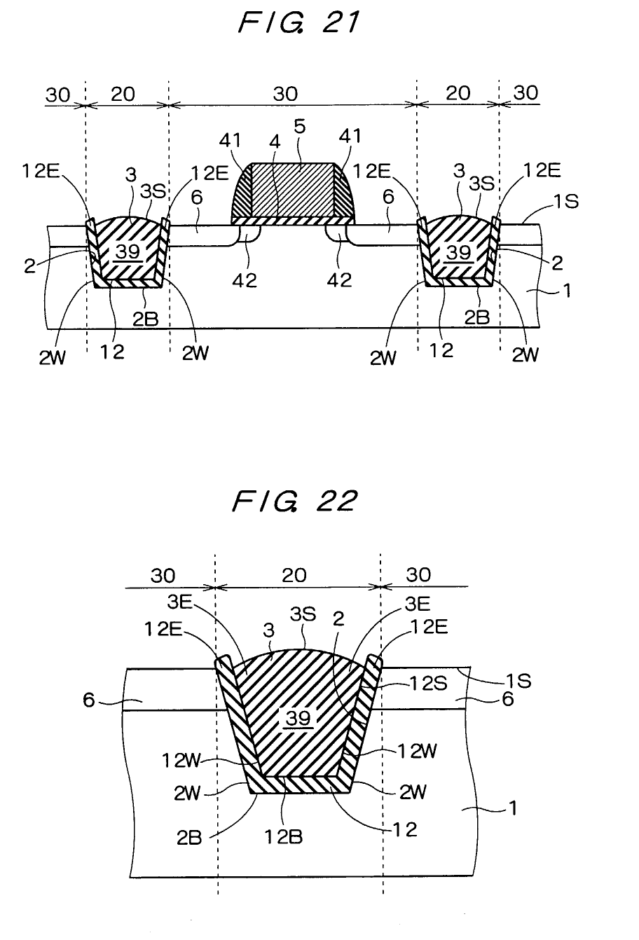

The basic structure of the MOSFET according to the third preferred embodiment of the present invention will be described with reference to FIGS. 21 and 22. FIG. 21 is a schematic vertical sectional view of the MOSFET according to the third preferred embodiment of the present invention. FIG. 22 is an enlarged view of the isolation region 20 of FIG. 21 and its surrounding parts. As shown in FIGS. 21 and 22, the MOSFET of the third preferred embodiment features the structure in the trenches 2, that is, the structure of trench-type isolations 39 to be described below. Hence, this structure is mainly described, and other elements similar to those of the MOSFET of the first and second preferred embodiments are designated by like reference characters for reference to the description thereon in the first and second preferred embodiments.

As illustrated in FIGS. 21 and 22, the MOSFET of the third preferred embodiment includes a silicon oxy-nitride 12 having a predetermined thickness and formed-on the inner wall and bottom faces 2W and 2B of each of the trenches 2. In particular, end portions 12E of the silicon oxy-nitride 12 which are adjacent to the edges thereof along the opening of each trench 2 are located at a higher level than the main surface 1S of the semiconductor substrate 1.

A silicon oxide 3 is formed on inner wall faces 12W and a bottom face 12B of the silicon oxy-nitride 12 along the inner wall and bottom faces 2W and 2B to completely fill each trench 2. The surface 3S of the silicon oxide 3 is substantially level with the main surface 1S.

In other words, the silicon oxy-nitride 12 formed along the inner wall and bottom faces 2W and 2B of each trench 2 does not completely fill each trench 2, and the silicon oxide 3 formed on the surface 12S of the silicon oxy-nitride 12 (parts of the entire surface of the silicon oxy-nitride 12 which are not in contact with the inner wall and bottom faces 2W and 2B of each trench 2) completely fills each trench 2, as shown in FIG. 22, in the MOSFET of the third preferred embodiment. A structure for isolation which comprises the silicon oxy-nitride 12 and the silicon oxide 3 that fill each trench 2 is also referred to hereinafter as a “(trench-type or wedge-type) isolation 39.”

As shown in FIGS. 21 and 22, the MOSFET of the third preferred embodiment comprises the isolations 39 having no depressions at least along the opening of the trenches 2 to prevent changes in operating characteristic due to the depressions, providing effects similar to those of the MOSFET of the first preferred embodiment.

The method of fabricating the MOSFET according to the third preferred embodiment will be described hereinafter. In particular, the method of the third preferred embodiment features the process for fabricating the isolations 39, and thus the fabrication step corresponding to the third step of the first preferred embodiment is mainly discussed.

(Third Step)

Initially, a silicon oxy-nitride 121 having a thickness of about 10 nm is formed on the entire exposed surface of the silicon substrate of FIG. 4 by the CVD process (See FIG. 23). In this step, the silicon oxy-nitride 121 is formed at least on the inner wall and bottom faces 2W and 2B of each trench 2.

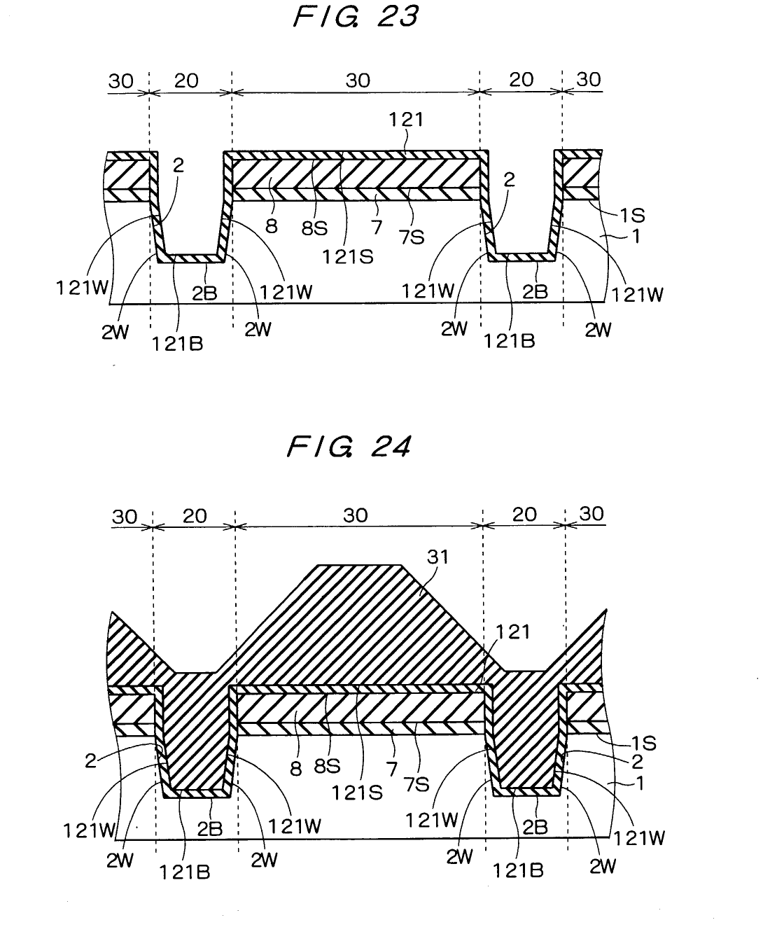

Referring to FIG. 24, a silicon oxide 31 having a thickness of 200 to 700 nm is formed over the surface 8S of the stopper film 8 and on the inner wall and bottom faces 121W and 121B of the silicon oxy-nitride 121 along the inner wall and bottom faces 2W and 2B. That is, the silicon oxide 31 entirely covers the surface 121S of the silicon oxynitride 121 and fills the trenches 2 up to at least the same level as the surface 8S of the stopper film 8. In this step, the above described advantage of the HDP-CVD process may be obtained when the HDP-CVD process is used to form the silicon oxide 31, as shown in FIG. 24.

A distinction is made hereinafter between the silicon oxide 31 present in the isolation region 20 which is referred to as a “buried oxide 31” and the silicon oxide 31 present in the active region 30 which is referred to as a “silicon oxide film 31,” as particularly required.

(Fourth to Sixth Steps)

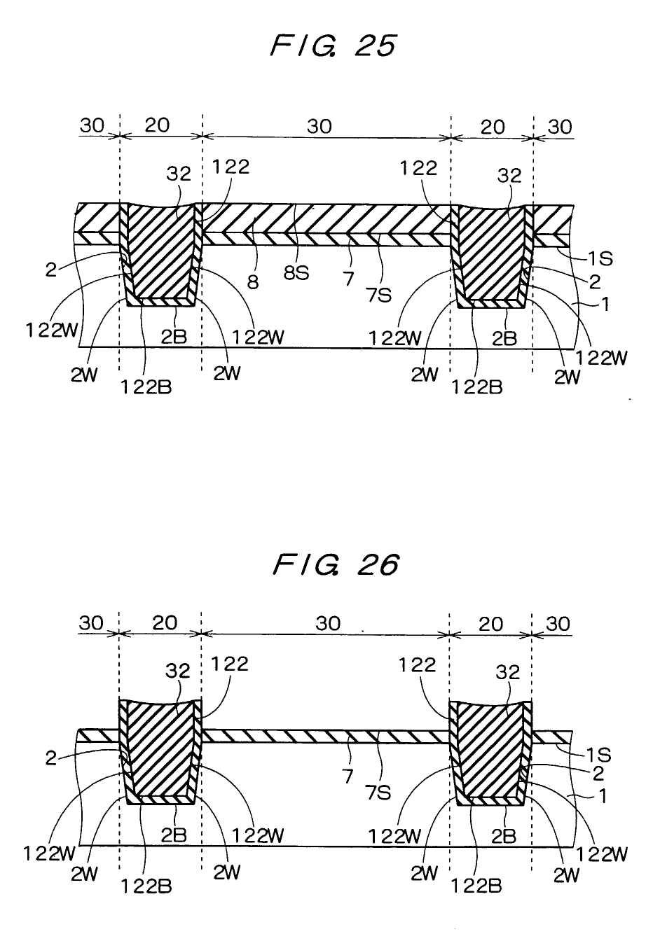

The silicon oxy-nitride 121 and the silicon oxide 31 serially formed on the surface 8S of the stopper film 8 are removed by the CMP process as in the fourth step of the first preferred embodiment (See FIG. 25). In this step, parts of the silicon oxy-nitride 121 which are formed on the inner wall and bottom faces 2W and 2B of the trenches 2 are left as a silicon oxy-nitride 122 shown in FIG. 25. The buried oxide 31 of FIG. 24 is removed to a level similar to the surface 8S so that a silicon oxide or buried oxide 32 shown in FIG. 25 is left in each of the trenches 2.

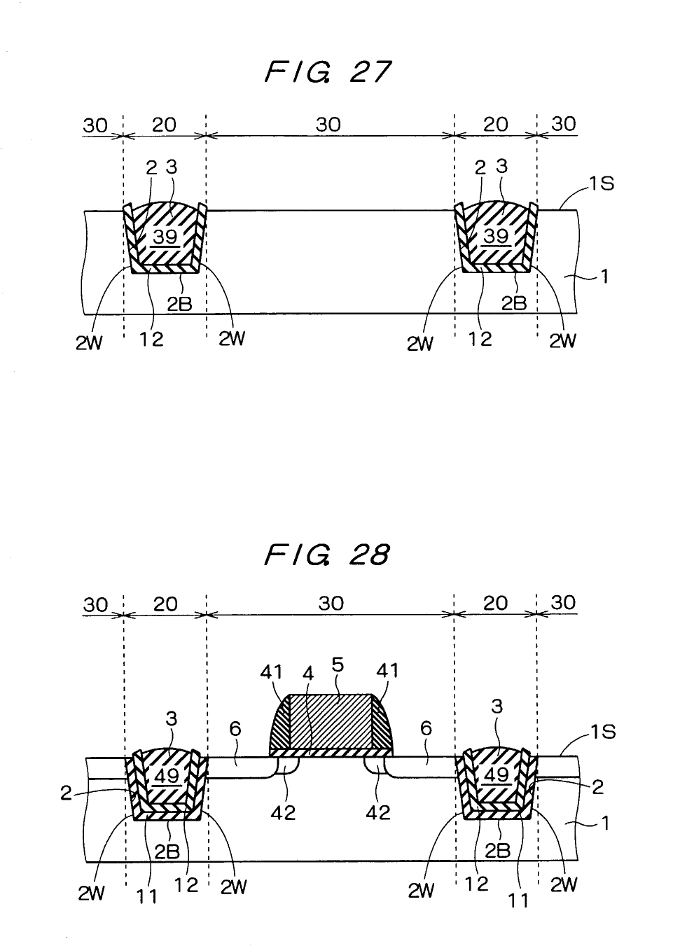

The silicon nitride film 8 is removed using phosphoric acid at elevated temperatures as in the fifth step of the first preferred embodiment (See FIG. 26). Subsequently, the silicon oxide film 7 is removed by wet etching using hydrofluoric acid (See FIG. 27). In this wet etching step, the buried oxide 32 and the silicon oxy-nitride 122 shown in FIG. 26 are partially etched. The trench-type (wedge-type) isolations 39 each comprising the silicon oxide or buried oxide 3 and the silicon oxy-nitride 12 formed in the trench 2 are completed, as shown in FIG. 27.

The MOSFET shown in FIG. 21 is completed through the fabrication step similar to the sixth step of the first preferred embodiment.

According to the method of the third preferred embodiment, as above described, the silicon oxy-nitride 121 is formed on the inner wall and bottom faces 2W and 2B of the trenches 2 in the third step to reduce the stresses caused in the subsequent heat treatment step. Therefore, the method of the third preferred embodiment, similar to the method of the first preferred embodiment, can fabricate the MOSFET which reliably accomplishes the predetermined operating characteristic without the stress-induced drawback, with a high yield.

In particular, if end portions 3E of the silicon oxide 3 (See FIG. 22) become lower than the main surface 1S of the semiconductor substrate 1 (or the end portions 3E of the silicon oxide 3 are depressed), the method of the third preferred embodiment may greatly suppress the unsatisfactory operating characteristic resulting from the depressions, as compared with the prior art MOSFET, since the silicon oxy-nitride 12 having the end portions 12E located at a higher level than the main surface 1S is reliably formed.

(Fourth Preferred Embodiment)

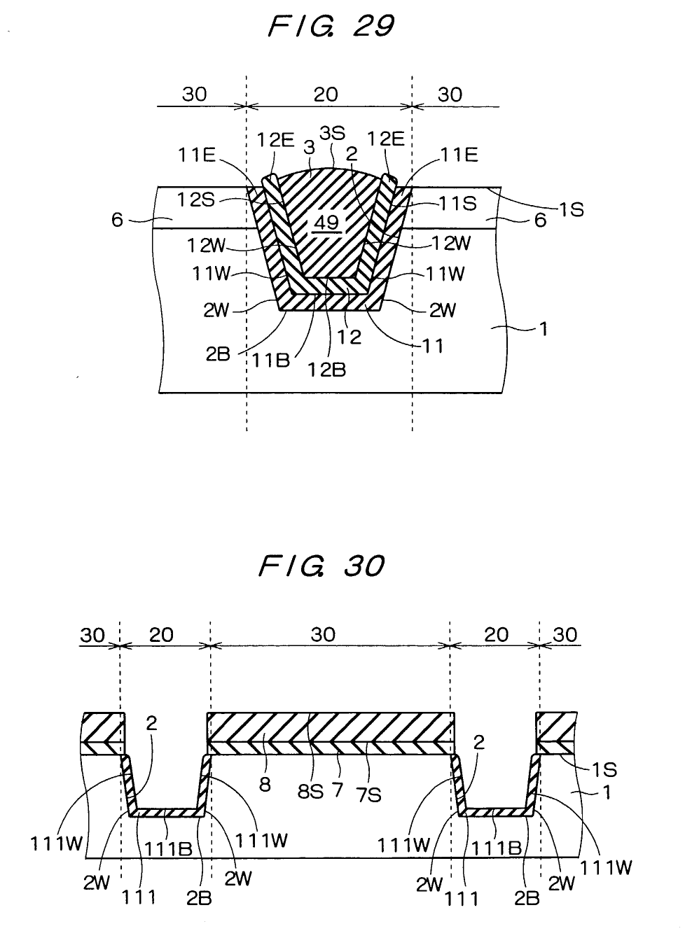

The basic structure of the MOSFET according to the fourth preferred embodiment of the present invention will be described with reference to FIGS. 28 and 29. FIG. 28 is a schematic vertical sectional view of the MOSFET according to the fourth preferred embodiment of the present invention. FIG. 29 is an enlarged view of the isolation region 20 of FIG. 28 and its surrounding parts. As shown in FIGS. 28 and 29, the MOSFET of the fourth preferred embodiment features the structure in the trenches 2, that is, the structure of trench-type isolations 49 to be described below. Hence, this structure is mainly described, and other elements similar to those of the MOSFET of the first to third preferred embodiments are designated by like reference characters for reference to the description thereon in the first to third preferred embodiments.

As illustrated in FIGS. 28 and 29, the MOSFET of the fourth preferred embodiment includes the silicon oxide film 11 formed on the inner wall and bottom faces 2W and 2B of each of the trenches 2. In particular, the end portions 11E of the silicon oxide film 11 along the opening of each trench 2 are substantially level with the main surface 1S of the semiconductor substrate 1. Part of the entire surface of the silicon oxide film 11 which is not in contact with the inner wall and bottom faces 2W and 2B is also referred to hereinafter as a “surface 11S” of the silicon oxide film 11.

Referring to FIG. 29, in particular, the silicon oxy-nitride 12 is formed on part of the surface 11S of the silicon oxide film 11. More specifically, the silicon oxy-nitride 12 having a predetermined thickness is formed on the inner wall and bottom faces 11W and 11B of the silicon oxide film 11 along the inner wall and bottom faces 2W and 2B of the trench 2. In particular, the end portions 12E of the silicon oxy-nitride 12 which are adjacent to the edges thereof along the opening of the trench 2 are located at a higher level than the main surface 1S of the semiconductor substrate 1.

The silicon oxide 3 is formed on the inner wall and bottom faces 12W and 12B of the silicon oxy-nitride 12 along the inner wall and bottom faces 2W and 2B to completely fill the trench 2. The surface 3S of the silicon oxide 3 is substantially level with the main surface 1S.

In other words, the silicon oxy-nitride 12 formed along the inner wall and bottom faces 2W and 2B of the trench 2 and the silicon oxide film 11 formed on the inner wall and bottom faces 2W and 2B of the trench 2 and in contact with the silicon oxy-nitride 12 do not completely fill the trench 2, and the silicon oxide 3 formed on the surface 12S of the silicon oxy-nitride 12 completely fills the trench 2, as shown in FIG. 29, in the MOSFET of the fourth preferred embodiment. A structure comprising the silicon oxide film 11, the silicon oxy-nitride 12 and the silicon oxide 3 which fill the trench 2 is also referred to hereinafter as an “isolation 49.”

As depicted in FIG. 29, the end portions 11E of the silicon oxide film 11 are substantially level with the main surface 1S of the semiconductor substrate 1, and the end portions 12E of the silicon oxy-nitride 12 are located at a higher level than the main surface 1S. Thus, the MOSFET of the fourth preferred embodiment comprises the isolations 49 having no depressions at least along the opening of the trenches 2 to prevent changes in operating characteristic due to the depressions, providing effects similar to those of the MOSFET of the first preferred embodiment.

Additionally, the MOSFET of the fourth preferred embodiment comprises the silicon oxide film 11 between the silicon oxy-nitride 12 and the inner wall and bottom faces 2W and 2B of the trenches 2 to sufficiently suppress the leakage current resulting from the interface state between the trenches 2 and the isolations 49, like the MOSFET of the second preferred embodiment. Therefore, the isolations 49 may provide an isolation characteristic which ensures the isolation of devices from each other. The method of the fourth preferred embodiment can provide the MOSFET which reliably accomplishes the predetermined operating characteristic.

The method of fabricating the MOSFET according to the fourth preferred embodiment is discussed below. In particular, the method of the fourth preferred embodiment features the process for fabricating the isolations 49, and thus the fabrication step corresponding to the third step of the first preferred embodiment is mainly discussed.

(Third Step)

The silicon substrate 1 shown in FIG. 4 is heat treated in an oxygen atmosphere at 1100° C. This thermally oxidizes parts of the silicon substrate 1 which are exposed at the inner wall and bottom faces 2W and 2B of each trench 2 to form the silicon oxide film (second silicon oxide film) 111 having a thickness of about 15 nm (See FIG. 30). The ranges of the isolation region 20 and the active region 30 after the formation of the silicon oxide film 111 which is a thermally oxidized film are defined in the manner described in the second preferred embodiment.

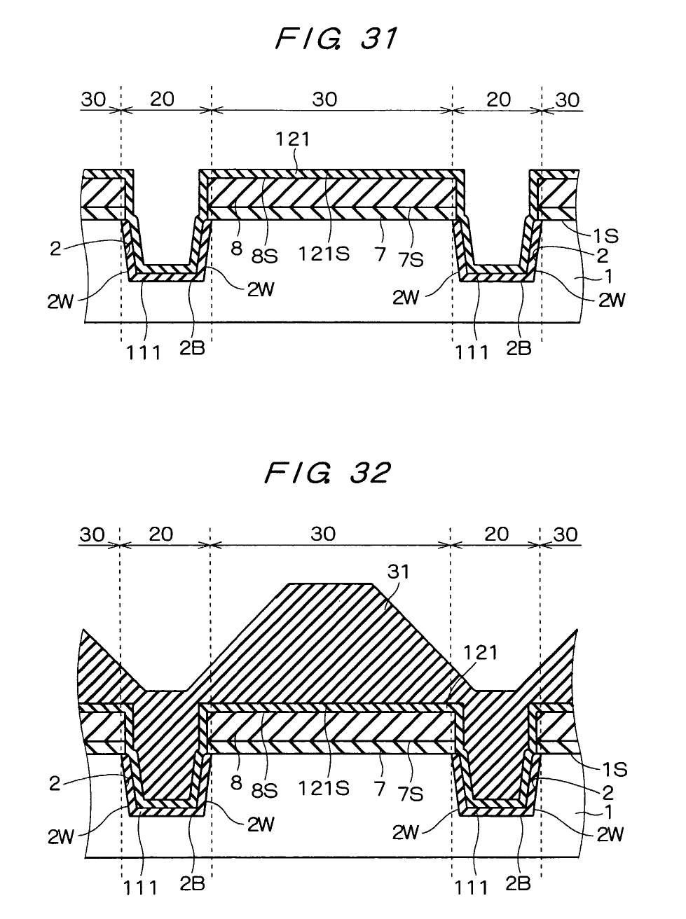

Then, the silicon oxy-nitride 121 having a thickness of about 10 nm is formed on the exposed surface of the semiconductor substrate 1 by the CVD process, more specifically on the surface 8S of the stopper film 8, on the inner wall and bottom faces 111W and 111B of the silicon oxide film 111 (See FIG. 30) and on parts of the silicon oxide film 7 and the stopper film 8 which define the inner wall faces 2W (See FIG. 31).

Then, the silicon oxide 31 having a thickness of 200 to 700 nm is formed on the exposed surface 121S of the silicon oxy-nitride 121 to fill the trenches 2 up to at least the same level as the surface 8S (See FIG. 32).

(Fourth to Sixth Steps)

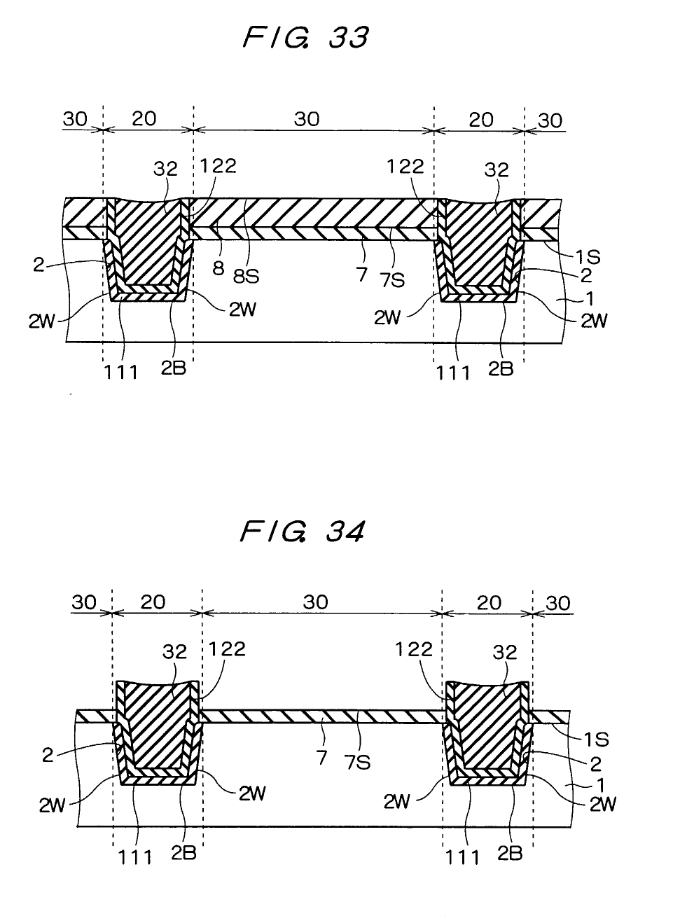

The silicon oxy-nitride 121 and the silicon oxide 31 on the surface 8S of the stopper film 8 are removed by the CMP process as in the fourth step of the first preferred embodiment (See FIG. 33). In this step, part of the silicon oxy-nitride 121 which is not formed on the surface 8S is left as the silicon oxy-nitride 122 of FIG. 33. The buried oxide 31 of FIG. 32 is removed to a level similar to the surface 8S so that the silicon oxide or buried oxide 32 of FIG. 33 is left in each of the trenches 2.

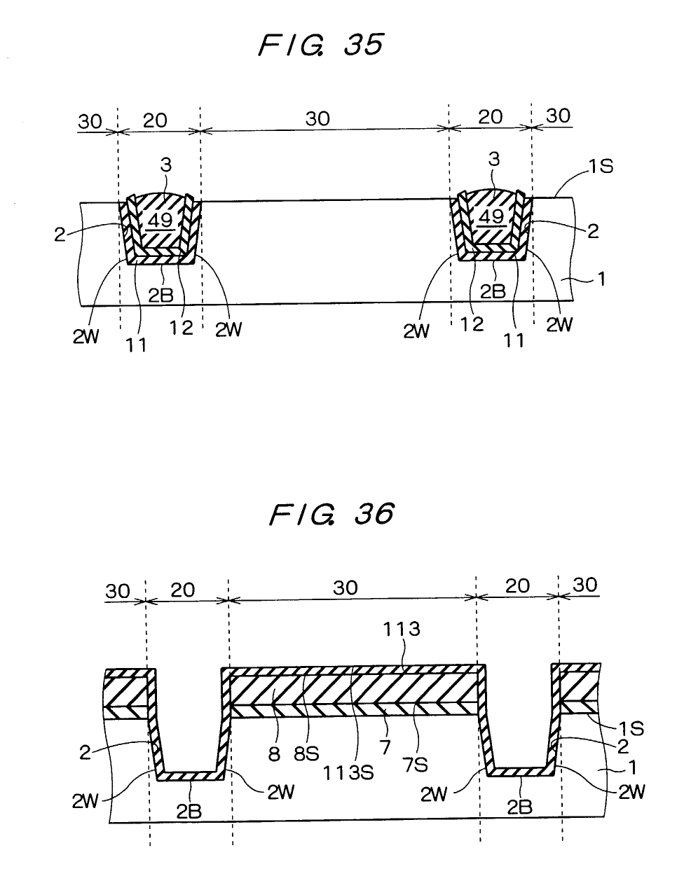

The silicon nitride film 8 is removed using phosphoric acid at elevated temperatures as in the fifth step of the first preferred embodiment (See FIG. 34). Subsequently, the silicon oxide film 7 is removed by wet etching using hydrofluoric acid (See FIG. 35). In this wet etching step, the buried oxide 32 and the silicon oxy-nitride 122 shown in FIG. 33 are partially etched. The trench-type (wedge-type) isolations 49 each comprising the silicon oxide or buried oxide 3, the silicon oxy-nitride 12 and the silicon oxide film 11 formed in the trench 2 are completed, as shown in FIG. 34.

The MOSFET shown in FIG. 28 is completed through the fabrication step similar to the sixth step of the first preferred embodiment.

As above described, the method of the fourth preferred embodiment comprises forming the silicon oxy-nitride 121 in the trenches 2 in the third step to reduce the stresses caused in the subsequent heat treatment step. Therefore, the method of the fourth preferred embodiment, similar to the method of the first preferred embodiment, can eliminate the stress-induced drawback to fabricate the MOSFET which reliably accomplishes the predetermined operating characteristic.

In particular, the silicon oxide film 11 is formed thin between the trenches 2 and the silicon oxy-nitride 12 to prevent the end portions 11E of the silicon oxide film 11 (See FIG. 29) from being excessively etched away when the silicon oxide film 7 is removed using the hydrofluoric acid in the fifth step in the method of the fourth preferred embodiment. This allows the end portions 11E to be substantially level with the main surface 1S of the semiconductor substrate 1, as shown in FIG. 29. Furthermore, the method of the fourth preferred embodiment can reliably form the silicon oxy-nitride 12 having the end portions 12E located at a higher level than the main surface 1S of the semiconductor substrate 1. Thus, if the end portions 3E of the silicon oxide 3 (corresponding to the end potions 3E of FIG. 22) along the trench opening become lower than the main surface 1S of the semiconductor substrate 1 (or the end portions 3E of the silicon oxide 3 are depressed), the method of the fourth preferred embodiment may greatly suppress the unsatisfactory operating characteristic resulting from the depressions, as compared with the prior art MOSFET.

Moreover, according to the method of the fourth preferred embodiment, in particular, the silicon oxide film 11 is formed by thermally oxidizing the inner wall and bottom faces 2W and 2B of the trenches 2. Therefore, the method of the fourth preferred embodiment, similar to the method of the second preferred embodiment, can reduce the interface state between the trenches 2 and the isolations 49 to fabricate the MOSFET which suppresses the drawback (e.g., the occurrence of the hump of FIG. 48) resulting from the concentration of the electric field on the end portion 30E of the active region 30, with a high yield.

(First Modification of Fourth Preferred Embodiment)

Description will be given on a method of forming the silicon oxide film 11 of the MOSFET shown in FIG. 28 by the CVD process as in the first modification of the second preferred embodiment.

(Third Step)

Initially, the silicon oxide film 113 having a thickness of about 10 nm is formed on the exposed surface of the silicon substrate 1 of FIG. 4 by the CVD process (See FIG. 36). At this time, the silicon oxide film (second silicon oxide film) 113 is formed at least on parts of the silicon substrate 1 which are exposed at the inner wall and bottom faces 2W and 2B of the trenches 2.

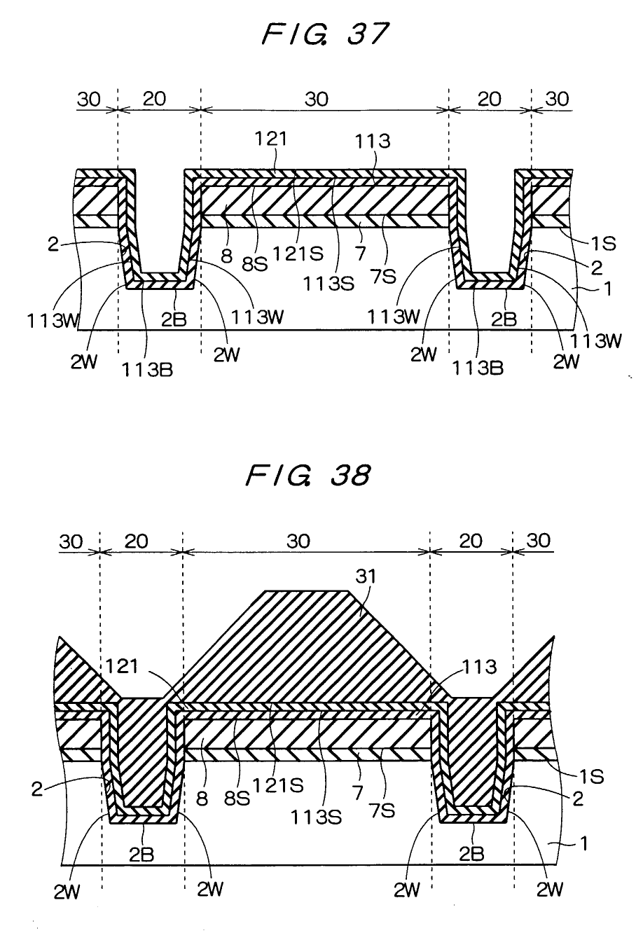

Then, the silicon oxy-nitride 121 having a thickness of about 10 nm is formed by the CVD process over the surface 8S of the stopper film 8 and on the inner wall and bottom faces 113W and 113B of the silicon oxide film 113 along the inner wall and bottom faces 2W and 2B, that is, on the entire exposed surface 113S of the silicon oxide film 113 (See FIG. 37).

Then, the silicon oxide 31 having a thickness of 200 to 700 nm is formed on the exposed surface 121S of the silicon oxy-nitride 121 to fill the trenches 2 up to at least the same level as the surface 8S (See FIG. 38).

(Fourth to Sixth Steps)

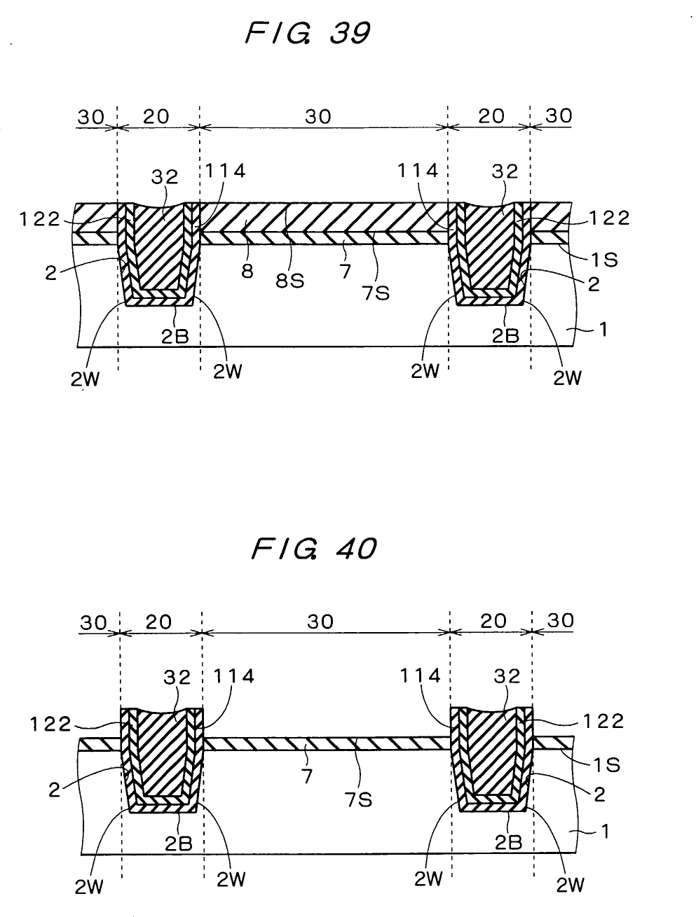

The silicon oxide film 31, the silicon oxy-nitride 121 and the silicon oxide film 113 serially formed on the surface 8S of the stopper film 8 are removed by the CMP process as in the fourth step of the first preferred embodiment (See FIG. 39). In this step, the above-mentioned buried oxide 32 is left, and parts of the silicon oxide film 113 and the silicon oxy-nitride 121 of FIG. 38 which are not formed over the surface 8S are left as the silicon oxide film 114 and the silicon oxy-nitride 122 of FIG. 39, respectively.

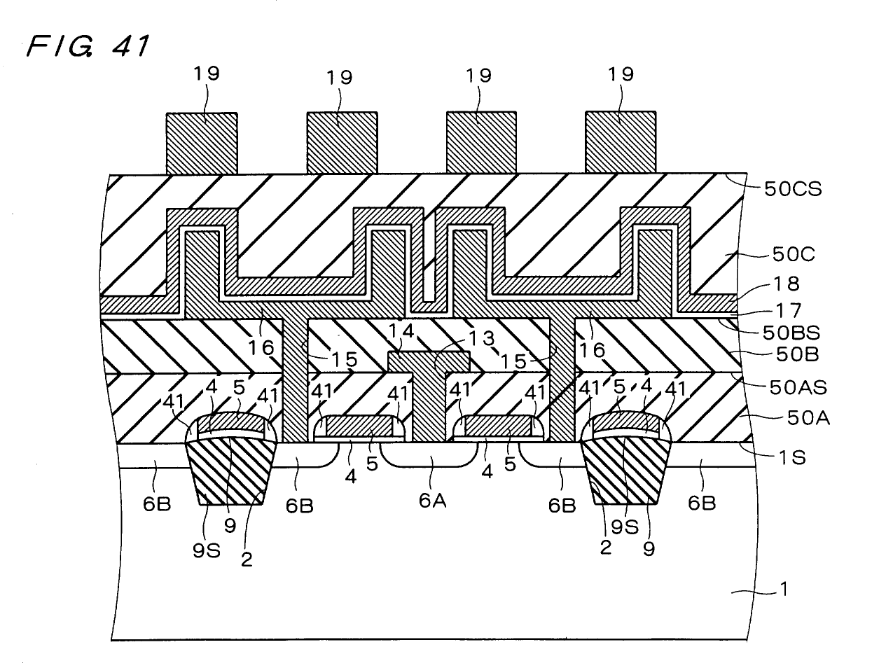

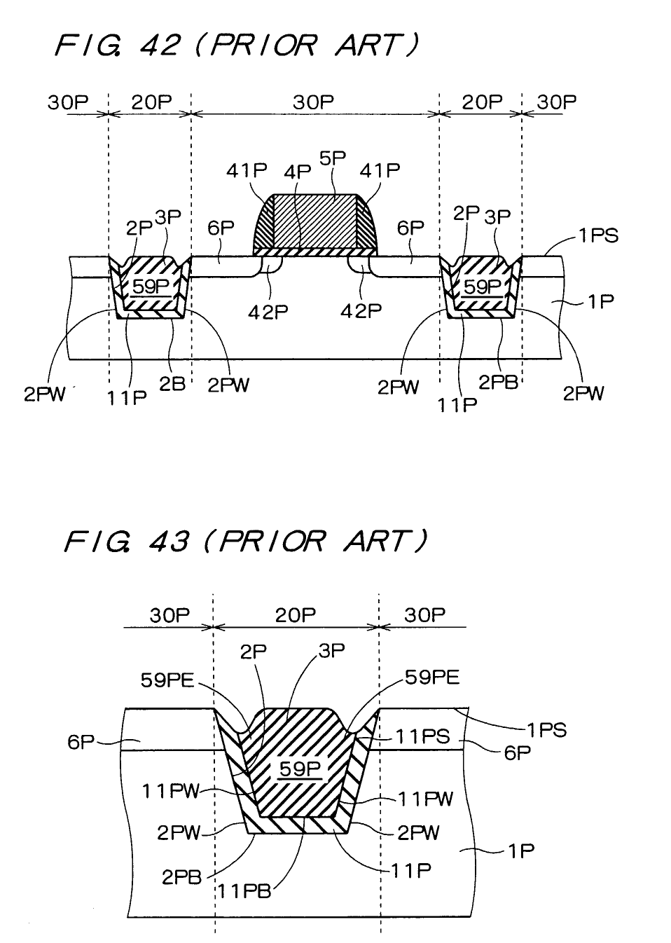

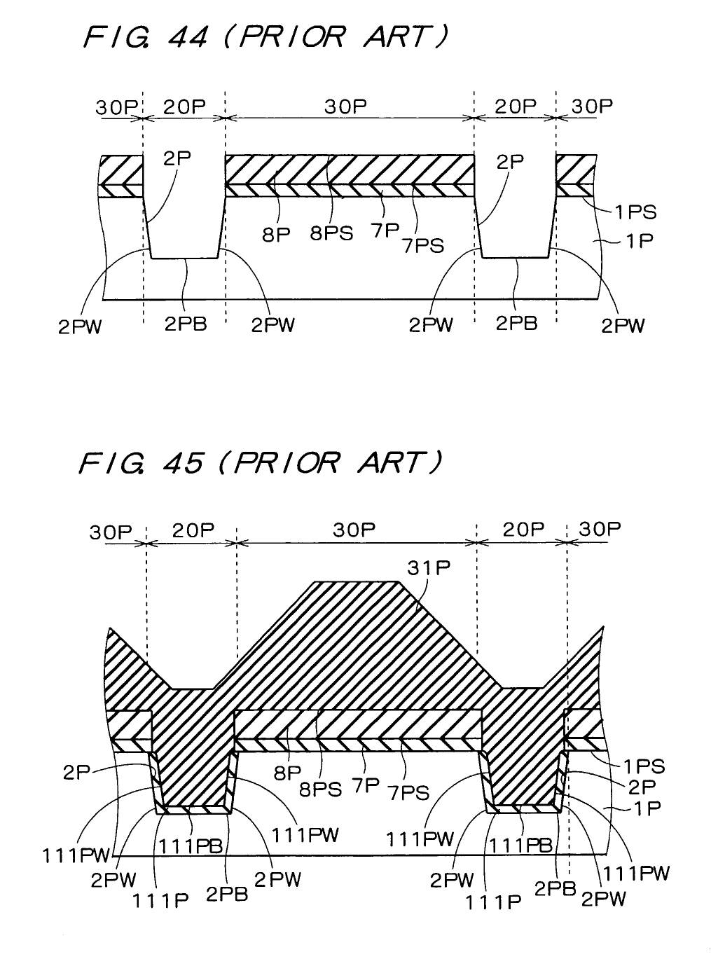

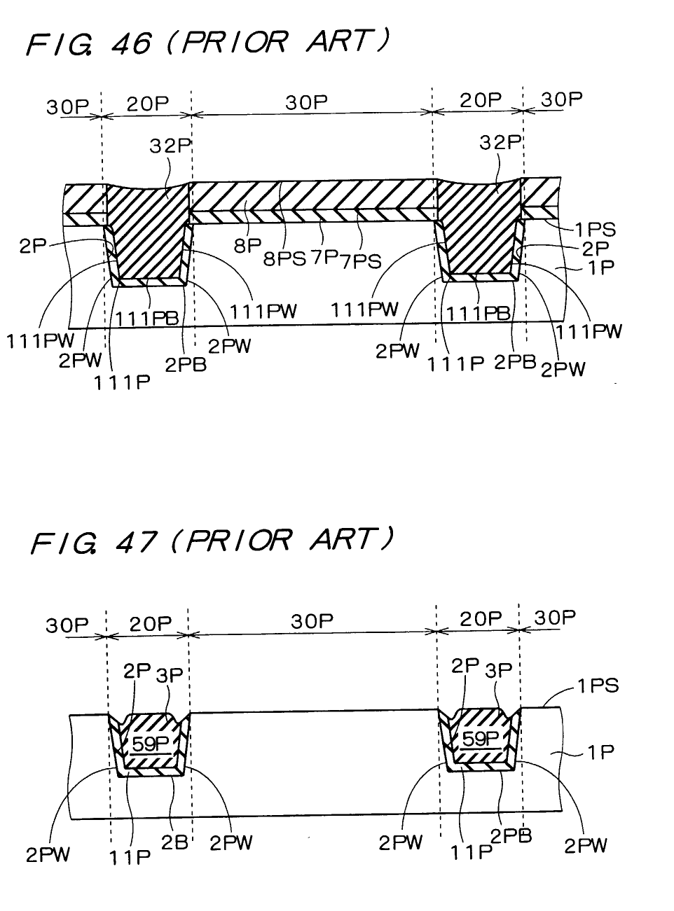

The silicon nitride film 8 is removed using phosphoric acid at elevated temperatures as in the fifth step of the first preferred embodiment (See FIG. 40). Subsequently, the silicon oxide film 7 is removed by wet etching using hydrofluoric acid (See FIG. 35). In this wet etching step, the buried oxide 32, the silicon oxy-nitride 122 and the silicon oxide film 114 shown in FIG. 40 are partially etched. The trench-type (wedge-type) isolations 49 are completed as shown in FIG. 35.

The MOSFET shown in FIG. 28 is completed through the fabrication step similar to the sixth step of the first preferred embodiment.

In particular, the method of the first modification of the fourth preferred embodiment, in which the silicon oxide film 111 is formed by the CVD process, is advantageous in fabricating the MOSFET which suppresses the reduction in current driving capability, like the MOSFET of the first modification of the second preferred embodiment.

A conventional structure of the semiconductor device having a trench-type isolation comprising a silicon oxide film formed on the inner wall and bottom faces of the trench, a silicon oxy-nitride formed on the surface of the silicon oxide film along the inner wall and bottom faces of the trench, and a silicon oxide formed on the surface of the silicon oxy-nitride is disclosed in Japanese Patent Application Laid-Open No. P07-176606A (1995) (referred to hereinafter as Reference (4)).

The semiconductor device proposed in Reference (4) includes a trench-type isolation comprising, for example, 1 μm-based wide and narrow trenches which differ in construction from each other. More specifically, the above described three-layer trench-type isolation is formed in the wide trench, and a two-layer trench-type isolation comprising a silicon oxide film formed on the inner wall and bottom faces of the trench and a silicon oxy-nitride formed on the surface of the silicon oxide film is formed in the narrow trench. The MOSFET of the fourth preferred embodiment and the first modification thereof has a structural difference from that of Reference (4) in that all of the trenches are filled with the trench-type isolation 49 comprising the silicon oxide film 11, the silicon oxy-nitride 12 and the silicon oxide 3.

Further, when the silicon oxy-nitride constituting the three-layer trench-type isolation is chemically dry etched to form the isolation, the difference in etch rate between the silicon oxy-nitride and the silicon oxide causes a central portion of the isolation to be at a higher level than the semiconductor substrate surface. The isolation 49 of the fourth preferred embodiment and the first modification thereof is designed so that the surface thereof (particularly the surface of the silicon oxy-nitride 12) is at a higher level than the main surface 1S of the semiconductor substrate 1, whereas the isolation of Reference (4) is not intentionally formed into the above described structure. Moreover, the method of Reference (4), similar to those of References (1) to (3), comprises forming the silicon oxide film (thermally oxidized film), the silicon oxy-nitride and the silicon oxide (formed by the CVD process) in the order named directly on the surface of the semiconductor substrate with the trench formed therein. Thus, the isolation of Reference (4) includes end portions having depressions lower than the surface of the semiconductor substrate. This is considered to result in the unsatisfactory operating characteristic of the semiconductor device due to the depressions.

(Application)

In the first to fourth preferred embodiments, the MOSFET is used as an example of the semiconductor device, and description has been given on the structure of the MOSFET having the trench-type isolations 9, 29, 39 and 49 which are the feature of the present invention, and the method of fabricating the same. A DRAM will be used herein as another example of the semiconductor device, and description will be given on a structure of the DRAM having the trench-type isolations 9 of the first preferred embodiment.

FIG. 41 is a schematic vertical sectional view of a DRAM according to an application of the first preferred embodiment. Elements similar to those of the MOSFET of the first preferred embodiment are designated by like reference characters for reference to the description thereon in the first preferred embodiment.

As illustrated in FIG. 41, the trenches 2 extend a predetermined depth from a predetermined region of the main surface 1S of the silicon substrate 1 toward the inside thereof. Each of the trenches 2 is completely filled with the trench-type isolation 9 comprising a silicon oxy-nitride. As described above, such an isolation 9 itself specifies the isolation region, and defines the active region which is other than the isolation region. The isolation 9 is formed by the above-mentioned method of the first preferred embodiment (in the first to fifth steps).

Two gate insulation films 4 spaced a predetermined distance apart from each other are formed on the main surface 1S in the active region. The gate electrode 5 and the sidewall oxide films 41 are formed on each of the gate insulation films 4. The gate insulation film 4, the gate electrode 5 and the sidewall oxide films 41 are shown as formed also on the surface 9S of each isolation 9. These components (generically referred to hereinafter as “gate electrode components 4, 5 and 41”) are formed in other active regions not shown in FIG. 41 and extend in a direction perpendicular to the plane of the figure.

A source and drain diffusion layer 6A corresponding to the above-mentioned source and drain diffusion layers 6 (See FIG. 1) is formed in a region having a predetermined depth from the main surface 1S of the silicon substrate 1 in such a manner as to connect regions of the silicon substrate 1 which are adjacent to the positions immediately under respective opposite ends of the two gate insulation films 4 in the active region. Source and drain diffusion layers 6B corresponding to the above-mentioned source and drain diffusion layers 6 (See FIG. 1) are formed in respective regions having a predetermined depth from the main surface 1S in such a manner as to extend nearly from positions immediately under the respective ends of the two gate insulation films 4 which are closer to the isolations 9 to reach the isolations 9. The LDD layers 42 formed in the MOSFET of the first preferred embodiment (See FIG. 1) are also formed in some cases. Such a MOSFET structure is formed by the method of the first preferred embodiment (in the sixth step).

An interlayer insulation film 50A is formed to entirely cover the main surface 1S and the gate electrode components 4, 5 and 41. A connection hole 13 is formed which extends from the surface 50AS of the interlayer insulation film 50A to the source and drain diffusion layer 6A. A bit line 14 connected to the source and drain diffusion layer 6A is formed in the connection hole 13 and on the surface 50AS adjacent to the opening of the connection hole 13.

An interlayer insulation film 50B is formed to entirely cover the surface 50AS and the bit line 14. Connection holes 15 are formed which extend from the surface 50BS of the interlayer insulation film 50B to the source and drain diffusion layers 6B. The connection holes 15 are filled with an electrode material constituting a first portion of a storage node 16. The electrode material, that is, the storage node 16 is connected to the source and drain diffusion layers 6B. The storage node 16 further comprises a second portion formed on the surface 50BS and connected to the first portion, and a third portion connected to an end of the second portion and extending perpendicularly to the surface 50BS in the direction opposite from the silicon substrate 1.

A capacitor insulation film 17 is formed on the surface of the third portion of the storage node 16, on parts of the surface of the second portion which are not in contact with the surface 50BS and on parts of the surface 50BS which are not in contact with the storage node 16. A cell plate electrode 18 is formed on the surface of the capacitor insulation film 17 along the surface 50BS and the surface of the storage node 16. An interlayer insulation film 50C is formed to entirely cover the cell plate electrode 18, and a plurality of interconnect layers 19 are formed on the surface 50CS of the interlayer insulation film 50C. The interconnect layers 19 are connected at portions not shown in FIG. 41 to, for example, the gate electrodes 5.

The DRAM according to the application of the first preferred embodiment, which comprises the isolations 9 made of silicon oxy-nitride, can reduce the stresses caused between the silicon substrate 1 and the silicon oxy-nitride 9 in the heat treatment step after the formation of the isolations 9, as compared with a conventional DRAM including trench-type isolations made of silicon oxide. This significantly suppresses the crystal defects generated in the silicon substrate due to the stresses. Therefore, the DRAM according to the application of the first preferred embodiment reduces the junction leakage current in the source and drain diffusion layers 6B to greatly reduce the losses of electric charges stored in the storage node 16, as well as greatly suppressing the reduction in reliability of the gate insulation films 4 due to the crystal defects in the silicon substrate 1.

Further, the trench-type isolations each having the surface 9S located at a higher level than the main surface 1S of the silicon substrate 1 have no depressions at end portions along the opening of the trenches 2. Then, when a predetermined voltage is applied to the gate electrodes 5, the electric field from the gate electrodes 5 is prevented from being concentrated on the end portions of the active region (corresponding to the end portions 30E of FIG. 2) where the gate electrodes 5 are formed across the isolations 9 over the surface 9S of the isolations 9. Therefore, the DRAM reduces the leakage current (See the hump of FIG. 48) resulting from the concentration of the electric field, thereby to sufficiently reduce the losses of electric charges stored in the storage node 16.

As described hereinabove, the DRAM can exhibit the predetermined operating characteristic more reliably than the conventional DRAM having trench-type isolations made of silicon oxide. Applications of the trench-type isolations 29, 39 and 49 of the second to fourth preferred embodiments to the DRAM provide the above-mentioned effects resulting from the isolations 29, 39 and 49.

While the invention has been described in detail, the foregoing description is in all aspects illustrative and not restrictive. It is understood that numerous other modifications and variations can be devised without departing from the scope of the invention.

We claim:

1. A semiconductor device comprising:
a silicon substrate;
a trench extending a predetermined depth from a main surface of said silicon substrate inwardly of said silicon substrate and defining an isolation region in said silicon substrate; and
a silicon oxy-nitride formed in said trench,
wherein an end portion of said silicon oxy-nitride along an opening of said trench is located at a higher level than said main surface of said silicon substrate.

2. The semiconductor device according to claim 1,
wherein said silicon oxy-nitride fills said trench, and
wherein said silicon oxy-nitride has a surface of a height increasing from said end portion thereof toward a central portion thereof.

3. The semiconductor device according to claim 2,
wherein said silicon oxy-nitride is formed on inner wall faces and a bottom face of said trench.

4. The semiconductor device according to claim 2, further comprising:
a silicon oxide film formed on inner wall faces and a bottom face of said trench,
wherein said silicon oxy-nitride is formed on inner wall faces and a bottom face of said silicon oxide film along said inner wall faces and said bottom face of said trench, and
wherein an end portion of said silicon oxide film along the opening of said trench is substantially level with said main surface of said silicon substrate.

5. The semiconductor device according to claim 1,
wherein said silicon oxy-nitride is formed along inner wall faces and a bottom face of said trench and does not fill said trench,
said semiconductor device further comprising
a silicon oxide formed on a surface of said silicon oxy-nitride to fill said trench.

6. The semiconductor device according to claim 5,
wherein said silicon oxy-nitride is formed on said inner wall faces and said bottom face of said trench.

7. The semiconductor device according to claim 5, further comprising
a silicon oxide film formed on said inner wall faces and said bottom face of said trench and in contact with said silicon oxy-nitride,
wherein an end portion of said silicon oxide film along the opening of said trench is substantially level with said main surface of said silicon substrate.

8. A method of fabricating a semiconductor device, comprising the steps of:
(a) preparing a silicon substrate to form a first silicon oxide film and a stopper film including at least a silicon nitride film in the order named on a main surface of said silicon substrate;
(b) etching a portion resulting from said step (a) which extends a predetermined depth from a predetermined region of a surface of said stopper film inwardly of said silicon substrate to form a trench defining an isolation region and an active region other than said isolation region in said silicon substrate;
(c) forming a silicon oxy-nitride on said surface of said stopper film and along the inside of said trench;
(d) removing a film formed on said surface of said stopper film by a CMP process; and
(e) removing said stopper film and thereafter removing said first silicon oxide film by etching using hydrofluoric acid.

9. The method according to claim 8,
wherein said step (c) comprises the step of
forming said silicon oxy-nitride on said surface of said stopper film and on inner wall faces and a bottom face of said trench to fill said trench with said silicon oxy-nitride up to at least the same level as said surface of said stopper film.

10. The method according to claim 8,
wherein said step (c) comprises the steps of:
forming a second silicon oxide film on at least parts of said silicon substrate which are exposed at inner wall faces and a bottom face of said trench; and
forming said silicon oxy-nitride over said surface of said stopper film and over said inner wall faces and said bottom face of said trench to fill said trench with said silicon oxy-nitride up to at least the same level as said surface of said stopper film.

11. The method according to claim 10,
wherein said second silicon oxide film is formed by thermally oxidizing said inner wall faces and said bottom face of said trench.

12. The method according to claim 10,
wherein said second silicon oxide film is formed by a CVD process.

13. The method according to claim 8,
wherein said step (c) comprises the steps of:
forming said silicon oxy-nitride on at least inner wall faces and a bottom face of said trench; and
forming a silicon oxide over said surface of said stopper film and on inner wall faces and a bottom face of said silicon oxy-nitride along said inner wall faces and said bottom face of said trench to fill said trench with said silicon oxide up to at least the same level as said surface of said stopper film.

14. The method according to claim 8,
wherein said step (c) comprises the steps of:
forming a second silicon oxide film on at least parts of said silicon substrate which are exposed at inner wall faces and a bottom face of said trench;
forming said silicon oxy-nitride over said surface of said stopper film and over said inner wall faces and said bottom face of said trench; and
forming a silicon oxide on a surface of said silicon oxy-nitride to fill said trench with said silicon oxide up to at least the same level as said surface of said stopper film.

15. The method according to claim 14,
wherein said second silicon oxide film is formed by thermally oxidizing said inner wall faces and said bottom face of said trench.

16. The method according to claim 14,
wherein said second silicon oxide film is formed by a CVD process.
